(19) United States
(12) Patent Application Publication
(10) Pub. No.: US 2025/0318395 A1
(43) Pub. Date: Oct. 9, 2025

(54) DISPLAY DEVICE AND ELECTRONIC APPARATUS

(71) Applicant: Sony Group Corporation, Tokyo (JP)

(72) Inventor: Akitsuna Takagi, Tokyo (JP)

(21) Appl. No.: 18/866,001

(22) PCT Filed: Jun. 5, 2023
(86) PCT No.: PCT/JP23/20746

§ 371 Date: Nov. 14, 2024

(30) Foreign Application Priority Data
Jun. 23, 2022 (JP) 2022-100811

(51) Int. Cl. H10K 59/38; H10H 29/34; H10H 29/85; H10K 59/35; H10K 59/65

(52) U.S. Cl. CPC H10K 59/38; H10H 29/345; H10H 29/8517; H10K 59/352; H10K 59/353; H10K 59/65

(57) ABSTRACT

A display device includes a display region in which display pixels that emit visible light are arranged, and an adjacent region in which invisible light emitting pixels that emit at least invisible light in visible light and invisible light are arranged. The adjacent region is adjacent to the display region along an edge of the display region.

### FIELD

The present disclosure relates to a display device and an electronic apparatus.

### BACKGROUND

A display device that emits not only visible light but also infrared light is known (e.g., Patent Literature 1).

### CITATION LIST

### Patent Literature

Patent Literature 1: JP 2021-15731 A

### SUMMARY

### Technical Problem

There is a problem in arranging display pixels that emit visible light and invisible light emitting pixels that emit invisible light such as infrared light. When the invisible light emitting pixels are arranged at a position away from a display region where the display pixels are arranged, a substrate area increases, and the device is enlarged. When the invisible light emitting pixels are arranged in the display region, there is a possibility that display performance such as resolution and luminance deteriorates.

One aspect of the present disclosure is to suppress an increase in size of the device and a decrease in display performance.

### Solution to Problem

A display device according to one aspect of the present disclosure includes: a display region in which a display pixel that emits visible light is arranged; and an adjacent region in which an invisible light emitting pixel that emits at least invisible light in visible light and invisible light is arranged, the adjacent region being adjacent to the display region along an edge of the display region.

An electronic apparatus according to one aspect of the present disclosure includes: a display device including a display region in which a display pixel that emits visible light is arranged, and an adjacent region in which an invisible light emitting pixel that emits at least invisible light in visible light and invisible light is arranged, the adjacent region being adjacent to the display region along an edge of the display region; an imaging device that captures an image of invisible light; and an optical element that guides the invisible light from the adjacent region of the display device to a user and guides invisible light reflected by the user to the imaging device.

### BRIEF DESCRIPTION OF DRAWINGS

FIG. 1 is a diagram illustrating an example of a schematic configuration of a display device according to an embodiment.

FIG. 2 is a diagram illustrating an example of a schematic configuration of the display device according to the embodiment.

FIG. 3 is a diagram illustrating an example of the schematic configuration of the display device according to the embodiment.

FIG. 4 is a diagram illustrating an example of the schematic configuration of the display device according to the embodiment.

FIG. 5 is a diagram illustrating an example of the schematic configuration of the display device according to the embodiment.

FIG. 6 is a diagram illustrating an example of the schematic configuration of the display device according to the embodiment.

FIG. 7 is a diagram illustrating an example of a pixel configuration.

FIG. 8 is a diagram illustrating an example of the pixel configuration.

FIG. 9 is a diagram illustrating an example of the pixel configuration.

FIG. 10 is a diagram illustrating an example of the pixel configuration.

FIG. 11 is a diagram illustrating an example of the pixel configuration.

FIG. 12 is a diagram illustrating an example of the pixel configuration.

FIG. 13 is a diagram illustrating an example of the pixel configuration.

FIG. 14 is a diagram illustrating an example of the pixel configuration.

FIG. 15 is a diagram illustrating an example of the pixel configuration.

FIG. 16 is a diagram illustrating an example of the pixel configuration.

FIG. 17 is a diagram illustrating an example of the pixel configuration.

FIG. 18 is a diagram illustrating an example of the pixel configuration.

FIG. 19 is a diagram illustrating an example of the pixel configuration.

FIG. 20 is a diagram illustrating an example of the pixel configuration.

FIG. 21 is a diagram illustrating an example of the pixel configuration.

FIG. 22 is a diagram illustrating an example of the pixel configuration.

FIG. 23 is a diagram illustrating an example of the pixel configuration.

FIG. 24 is a diagram illustrating an example of the pixel configuration.

FIG. 25 is a diagram illustrating an example of the pixel configuration.

FIG. 26 is a diagram illustrating an example of the pixel configuration.

FIG. 27 is a diagram illustrating an example of the pixel configuration.

FIG. 28 is a diagram illustrating an example of the pixel configuration.

FIG. 29 is a diagram illustrating an example of the pixel configuration.

FIG. 30 is a diagram illustrating an example of the pixel configuration.

FIG. 31 is a diagram illustrating an example of the pixel configuration.

FIG. 32 is a diagram illustrating an example of the pixel configuration.

FIG. 33 is a diagram illustrating an example of the pixel configuration.

FIG. 34 is a diagram illustrating an example of the pixel configuration.

FIG. 35 is a diagram illustrating an example of the pixel configuration.

FIG. 36 is a diagram illustrating an example of the pixel configuration.

FIG. 37 is a diagram illustrating an example of a schematic configuration of an electronic apparatus.

FIG. 38 is a diagram illustrating an example of the schematic configuration of the electronic apparatus.

FIG. 39 is a diagram illustrating a modified example.

FIG. 40 is a diagram illustrating a modified example.

FIG. 41 is a diagram illustrating a modified example.

FIG. 42 is a diagram illustrating a modified example.

FIG. 43 is a diagram illustrating a modified example.

FIG. 44 is a diagram illustrating a modified example.

FIG. 45 is a diagram illustrating a modified example.

FIG. 46 is a diagram illustrating a modified example.

FIG. 47 is a diagram illustrating a modified example.

FIG. 48 is a diagram illustrating a modified example.

FIG. 49 is a diagram illustrating a modified example.

FIG. 50 is a diagram illustrating a modified example.

FIG. 51 is a diagram illustrating a modified example.

FIG. 52 is a diagram illustrating a modified example.

FIG. 53 is a diagram illustrating an application example.

FIG. 54 is a diagram illustrating an application example.

FIG. 55 is a diagram illustrating an application example.

FIG. 56 is a diagram illustrating an application example.

FIG. 57 is a diagram illustrating an application example.

FIG. 58 is a diagram illustrating an application example.

FIG. 59 is a diagram illustrating an application example.

FIG. 60 is a diagram illustrating an application example.

### DESCRIPTION OF EMBODIMENTS

Hereinafter, embodiments of the present disclosure will be described with reference to the drawings. In each of the following embodiments, the same components are given the same reference signs to omit redundant description.

The present disclosure will be described according to the following item order.
1. Embodiment
2. Modified examples
3. Examples of effect
4. Other modified examples
5. Application examples

### 1. EMBODIMENT

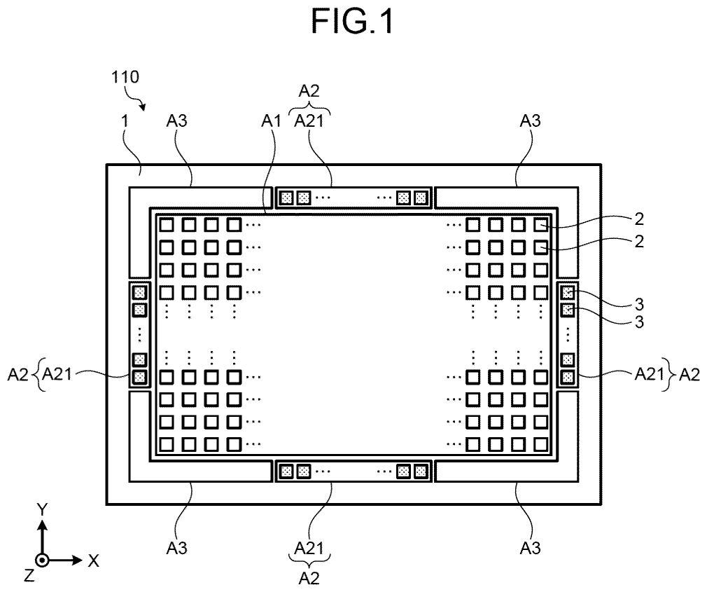

FIGS. 1 to 6 are diagrams illustrating examples of a schematic configuration of a display device according to an embodiment. A display device 110 includes a substrate 1, a plurality of display pixels 2, and one or more invisible light emitting pixels 3. The display pixel 2 and the invisible light emitting pixel 3 are provided on the substrate 1.

The substrate 1 can be formed of, for example, a glass substrate such as high strain point glass, soda glass, borosilicate glass, forsterite, lead glass, or quartz glass, a semiconductor substrate such as amorphous silicon or polycrystalline silicon, a resin substrate such as polymethyl methacrylate, polyvinyl alcohol, polyvinyl phenol, polyether sulfone, polyimide, polycarbonate, polyethylene terephthalate, or polyethylene naphthalate, or the like. An XYZ coordinate system is also indicated in the drawings. An X-axis direction and a Y-axis direction (XY plane direction) correspond to a plane direction of the substrate 1. A 2-axis direction corresponds to a thickness direction of the substrate 1. The display device 110 emits light toward a Z-axis positive direction side.

The display pixel 2 is a pixel that emits visible light. Examples of the visible light include red light, green light, and blue light. Unless otherwise specified, the visible light is red light, green light, and blue light. The visible light emitted from the display pixel 2 may be visible light for image display. An image may be understood to have a meaning including a video, and an image and a video may be mutually replaced as appropriate as long as there is no contradiction.

The invisible light emitting pixel 3 is a pixel that emits at least invisible light in visible light and invisible light. Examples of the invisible light include infrared light and ultraviolet light. Unless otherwise specified, the invisible light is assumed to be infrared light. The infrared light, the invisible light, and the ultraviolet light may be mutually replaced as appropriate as long as there is no contradiction. Note that the invisible light emitting pixels 3 are hatched in FIGS. 1 to 6 in order to easily distinguish the invisible light emitting pixels 3 from the display pixels 2.

The display device 110 includes a plurality of regions. Examples of the region include a display region A1, an adjacent region A2, a common peripheral region A3, and a common peripheral region A4.

In the display region A1, at least the display pixel 2 of the display pixel 2 and the invisible light emitting pixel 3 is arranged. In the display region A1, a plurality of pixels is arranged in an array.

The adjacent region A2 is a region adjacent to the display region A1 along an edge of the display region A1. The invisible light emitting pixels 3 are arranged in the adjacent region A2. The adjacent region A2 includes at least one of an outer peripheral adjacent region A21 and an inner peripheral adjacent region A22.

The outer peripheral adjacent region A21 is at least a part of an outer peripheral region of the display region A1. The outer peripheral region of the display region A1 is a region extending along an edge of the display region A1 outside the display region A1.

The inner peripheral adjacent region A22 is at least a part of an inner peripheral region of the display region A1. The inner peripheral region of the display region A1 is a region extending along an edge of the display region A1 inside the display region A1.

The common peripheral region A3 is at least a part of an outer peripheral region of the display region A1. An example of the common peripheral region A3 is a common electrode region of the visible light emitting element. Another example of the common peripheral region A3 is a circuit region of the visible light emitting element. Unless otherwise specified, the common peripheral region A3 is the common electrode region of the visible light emitting element.

The common peripheral region A4 is a part of the outer peripheral region of the display region A1. An example of the common peripheral region A4 is a common electrode region of the invisible light emitting element. Another example of the common peripheral region A4 is a circuit region of the invisible light emitting element. Unless otherwise specified, the common peripheral region A4 is the common electrode region of the invisible light emitting element.

Examples of a region layout are illustrated in FIGS. 1 to 6. In the example illustrated in FIG. 1, the adjacent region A2 is the outer peripheral adjacent region A21. Here, the outer peripheral adjacent region A21 is a part of an outer peripheral region of the display region A1. The outer peripheral region of the display region A1 includes the outer peripheral adjacent region A21 and the common peripheral region A3. The outer peripheral adjacent region A21 does not overlap the common peripheral region A3.

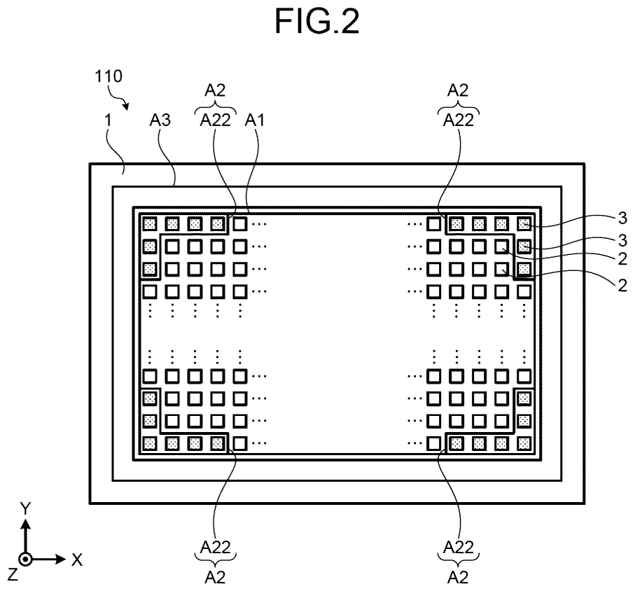

In an example illustrated in FIG. 2, the adjacent region A2 is the inner peripheral adjacent region A22. Here, the inner peripheral adjacent region A22 is a part of an inner peripheral region of the display region A1, and more specifically, is a corner region of the display region A1. The outer peripheral region of the display region A1 is the common peripheral region A3.

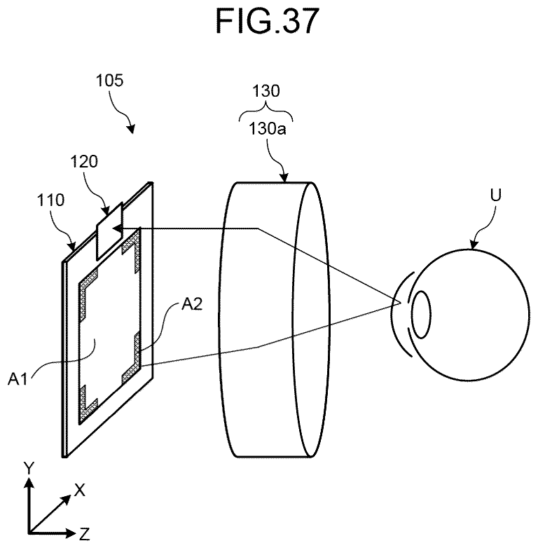

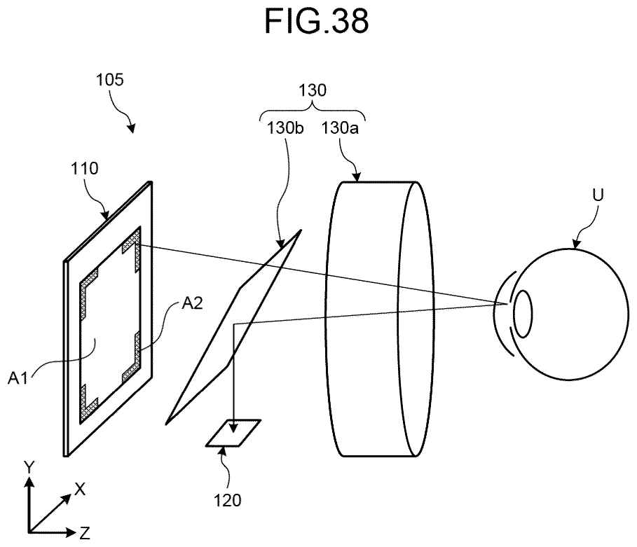

In the case that the display device 110 is observed through a magnifying lens (e.g., lens 130a in FIGS. 37 and 38 to be described later), the corner region of display region A1 may be a region where an image is not displayed in order to correct distortion aberration of a magnifying lens. By arranging the invisible light emitting pixels 3 in such a region, an influence on resolution of a display image and the like can be reduced.

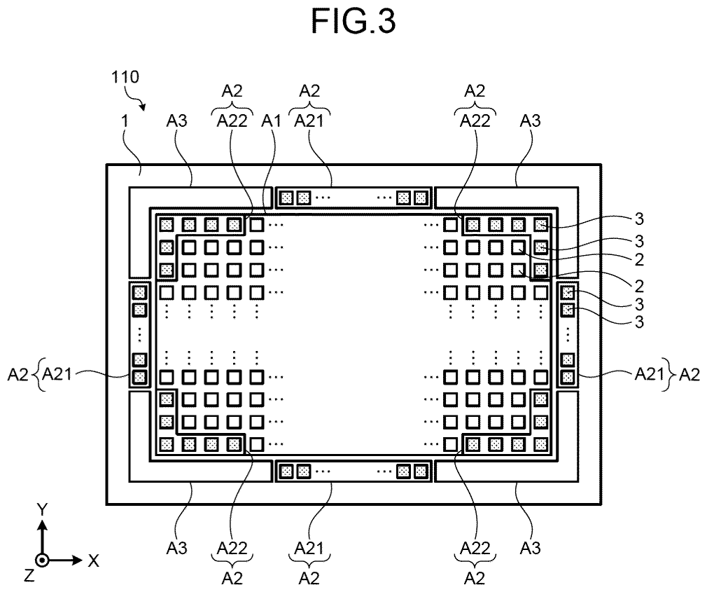

In an example illustrated in FIG. 3, the adjacent region A2 is both the outer peripheral adjacent region A21 and the inner peripheral adjacent region A22. Since a region layout in FIG. 3 can be described as a region layout obtained by combining FIGS. 1 and 2 described above, detailed description will not be repeated.

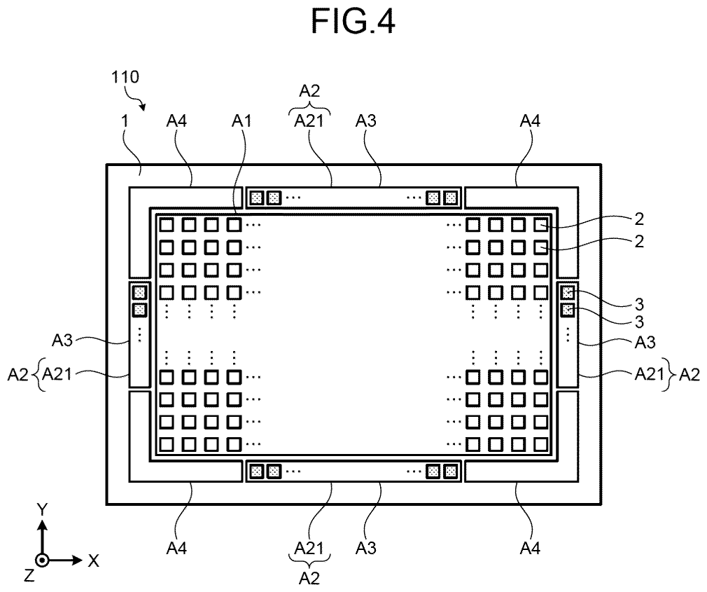

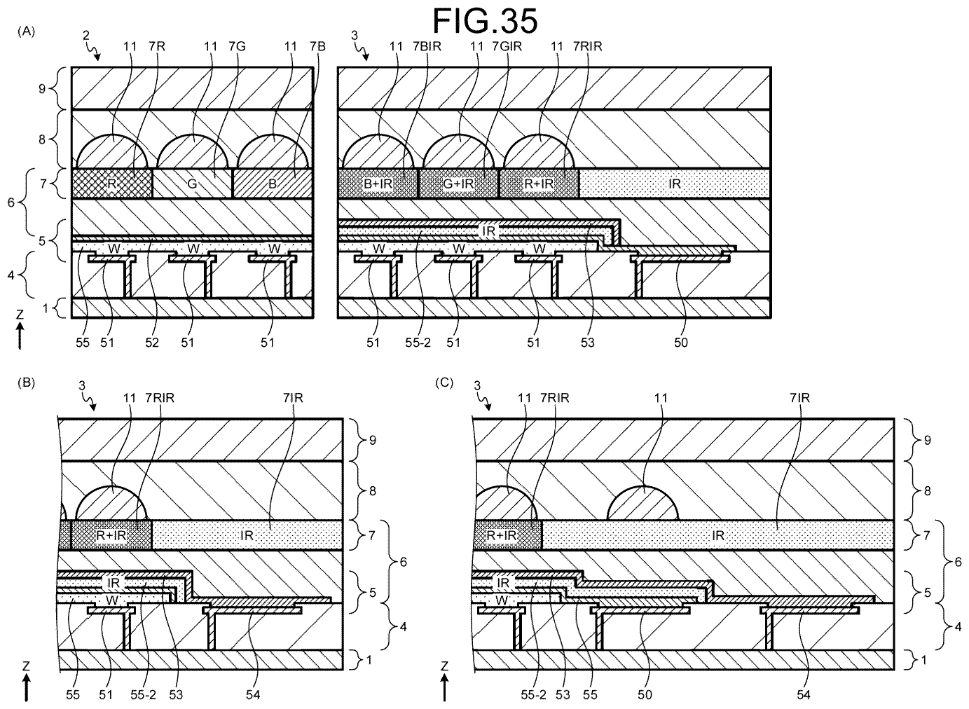

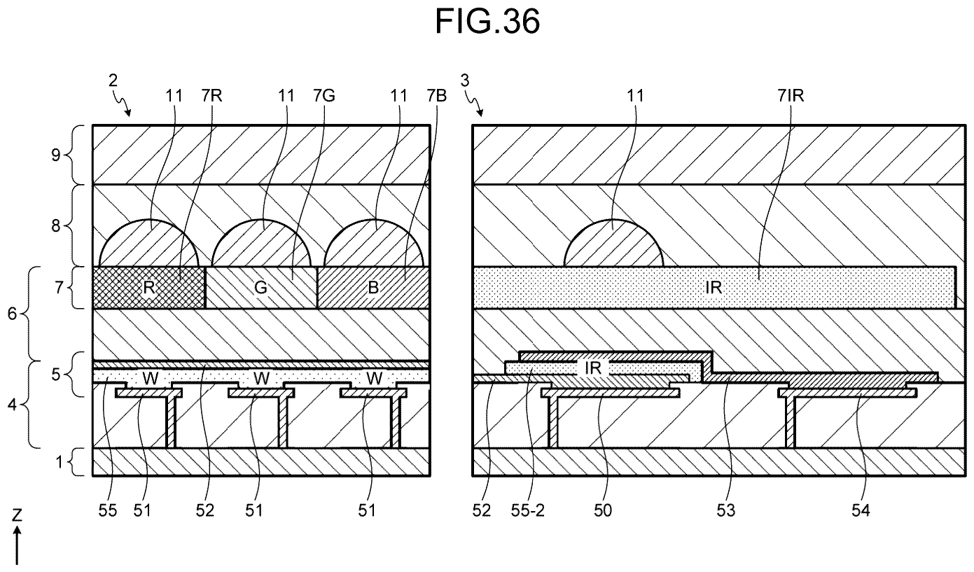

In an example illustrated in FIG. 4, the adjacent region A2 is the outer peripheral adjacent region A21. Here, the outer peripheral adjacent region A21 is a part of an outer peripheral region of the display region A1. The outer peripheral region of the display region A1 includes the outer peripheral adjacent region A21, the common peripheral region A3, and the common peripheral region A4. The outer peripheral adjacent region A21 overlaps the common peripheral region A3, but does not overlap the common peripheral region A4. The invisible light emitting pixels 3 arranged in the outer peripheral adjacent region A21 may have a pixel configuration in which a light emitting layer that emits invisible light and the common electrode of the invisible light emitting element are laminated (e.g., (C) of FIG. 35 and FIG. 36 described later).

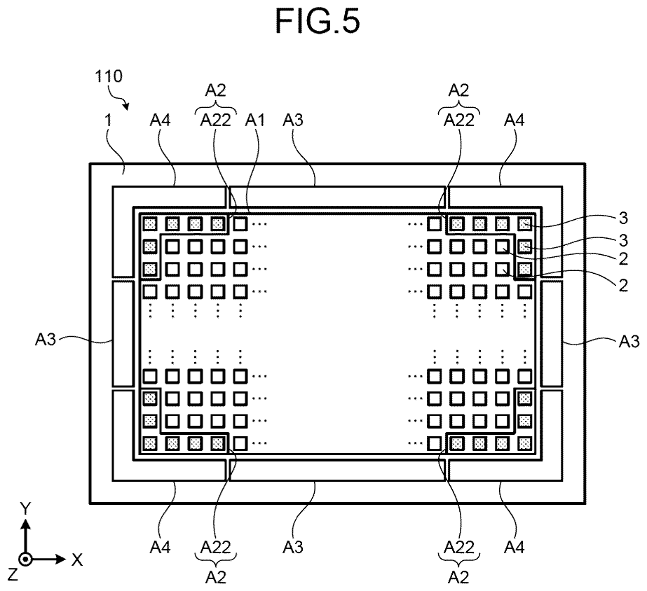

In an example illustrated in FIG. 5, the adjacent region A2 is the inner peripheral adjacent region A22. The inner peripheral adjacent region A22 is a part of the inner peripheral region of the display region A1, and more specifically, is the corner region of the display region A1. The invisible light emitting pixels 3 arranged here may have a pixel configuration in which the light emitting layer that emits visible light and the light emitting layer that emits invisible light are laminated (e.g., (A) of FIG. 35 described later). The outer peripheral region of the display region A1 includes the common peripheral region A3 and the common peripheral region A4. The common peripheral region A3 does not overlap the common peripheral region A4.

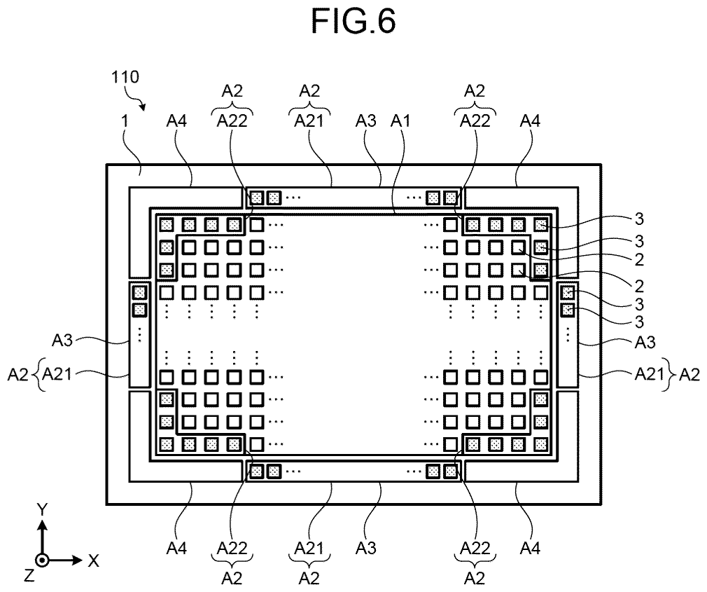

In an example illustrated in FIG. 6, the adjacent region A2 is both the outer peripheral adjacent region A21 and the inner peripheral adjacent region A22. Since a region layout of FIG. 6 can be described as a region layout obtained by combining FIGS. 4 and 5 described above, detailed description will not be repeated.

Note that FIGS. 1 to 6 illustrate a state in which the invisible light emitting pixels 3 are arranged in a row in the adjacent region A2, but the invisible light emitting pixels 3 may be arranged in two or more rows. Still more, only one invisible light emitting pixel 3 may be arranged. In a case where the plurality of invisible light emitting pixels 3 is arranged, an influence of a short circuit between electrodes (between a first electrode 51 and a second electrode 52 described later) due to foreign matter or the like can be reduced, for example, as compared with a case where only one invisible light emitting pixel 3 is arranged. In the inner peripheral adjacent region A22, the display pixels 2 and the invisible light emitting pixels 3 may be arranged in a mixed manner.

According to the display device 110 having the region layout as described above, the invisible light emitting pixels 3 are arranged in the adjacent region A2 adjacent to the display region A1 along an edge of the display region A1. As a result, for example, an increase in the area of the substrate 1 can be suppressed as compared with a case where the invisible light emitting pixel 3 is arranged at a position away from the display region A1. As a result, it is possible to suppress an increase in size of the display device 110. Furthermore, for example, as compared with a case where the invisible light emitting pixel 3 is arranged at a position away from the edge of the display region A1 in the display region A1, deterioration in display performance such as resolution and luminance can be suppressed.

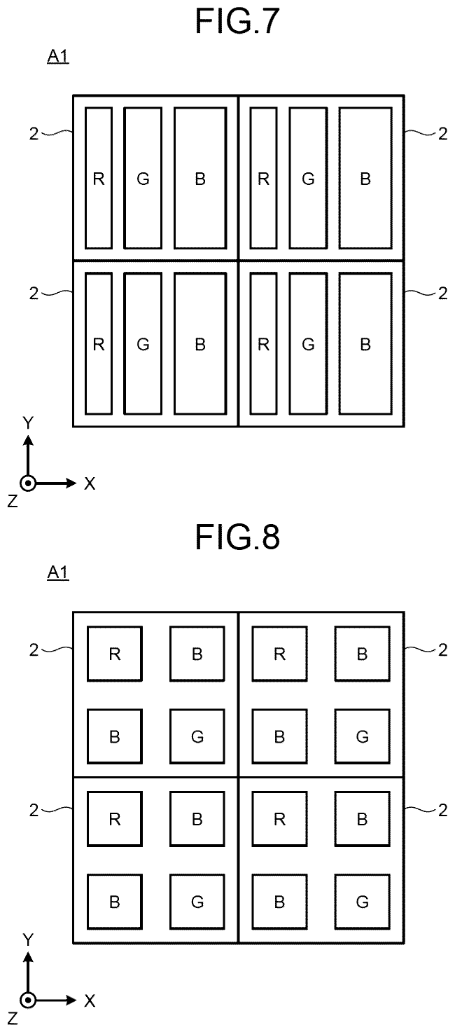

FIGS. 7 to 36 are diagrams illustrating examples of a pixel configuration. Among these, FIGS. 7 to 19 schematically illustrate the pixel configuration in plan view (as viewed in the Z-axis direction).

FIGS. 7 to 9 illustrate examples of a configuration of the display pixels 2 that can be arranged in the display region A1. The display pixel 2 includes a plurality of sub-pixels corresponding to different colors. Examples of the sub-pixels include a sub-pixel R, a sub-pixel G, and a sub-pixel B. The sub-pixel R emits red light. The sub-pixel G emits green light. The sub-pixel B emits blue light.

In the example illustrated in FIG. 7, each sub-pixel is arranged in a stripe manner such that one display pixel 2 includes one sub-pixel R, one sub-pixel G, and one sub-pixel B. One sub-pixel B may have an area (e.g., twice the area) larger than one sub-pixel R or one sub-pixel G.

In the example illustrated in FIG. 3, each sub-pixel is arranged in a square manner such that one display pixel 2 includes one sub-pixel R, one sub-pixel G, and two sub-pixels B. Each sub-pixel may have the same area.

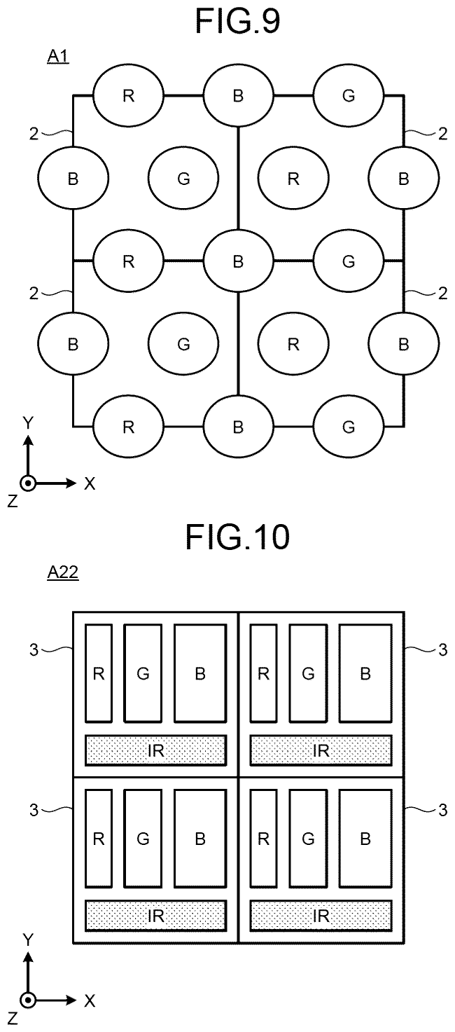

In the example illustrated in FIG. 9, each sub-pixel is arranged in a honeycomb manner such that one display pixel 2 includes one or more sub-pixels R, one or more sub-pixels G, and one or more sub-pixels B. Each sub-pixel may have the same type of shape and may have the same area.

FIGS. 10 to 12 illustrate examples of a configuration of the invisible light emitting pixels 3 that can be arranged in the inner peripheral adjacent region A22. The invisible light emitting pixels 3 exemplified emit not only invisible light but also visible light. It can also be said that the invisible light emitting pixel 3 is a pixel incorporating a function of the display pixel 2. By arranging such invisible light emitting pixels 3 in the inner peripheral adjacent region A22, an effect of suppressing deterioration in display performance can be further enhanced.

Specifically, the invisible light emitting pixel 3 includes the sub-pixel R, the sub-pixel G, the sub-pixel B, and a sub-pixel IR. The sub-pixel IR emits infrared light. In FIGS. 10 to 12, the sub-pixel IR is hatched in order to easily distinguish the sub-pixel IR from the sub-pixel R, the sub-pixel B, and the sub-pixel G. The same applies to FIGS. 13 to 19 described later.

In the example illustrated in FIG. 10, each sub-pixel is arranged in a stripe manner such that one invisible light emitting pixel 3 includes one sub-pixel R, one sub-pixel G, one sub-pixel G, and one sub-pixel IR. In this example, the sub-pixel IR is arranged so as to extend in a direction different from an extending direction of the sub-pixel R, the sub-pixel G, and the sub-pixel B. However, each sub-pixel may be arranged to extend in the same direction.

In the example illustrated in FIG. 11, each sub-pixel is arranged in a square manner such that the invisible light emitting pixel 3 includes one sub-pixel R, one sub-pixel G, one sub-pixel B, and one sub-pixel IR.

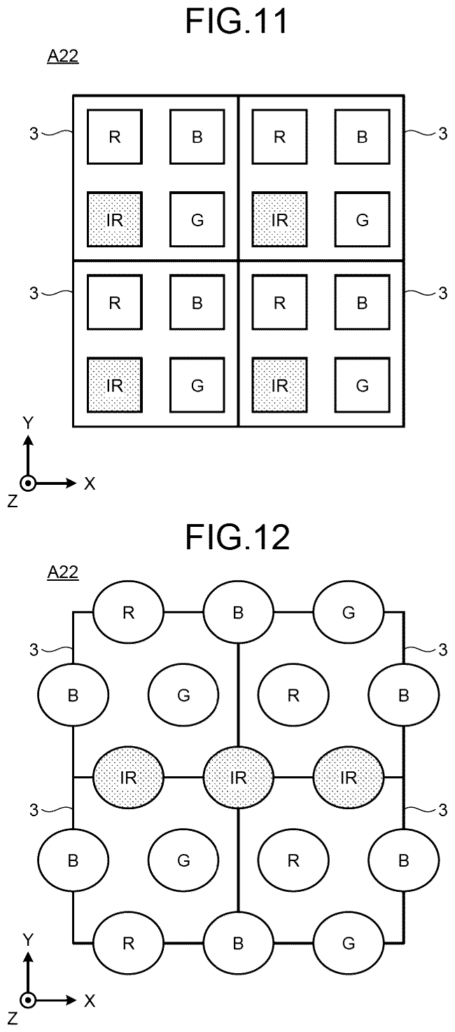

In the example illustrated in FIG. 12, each sub-pixel is arranged in a honeycomb manner such that one invisible light emitting pixel 3 includes one or more sub-pixels R, one or more sub-pixels G, one or more sub-pixels B, and one or more sub-pixels IR. Each sub-pixel may have the same type of shape or the same area.

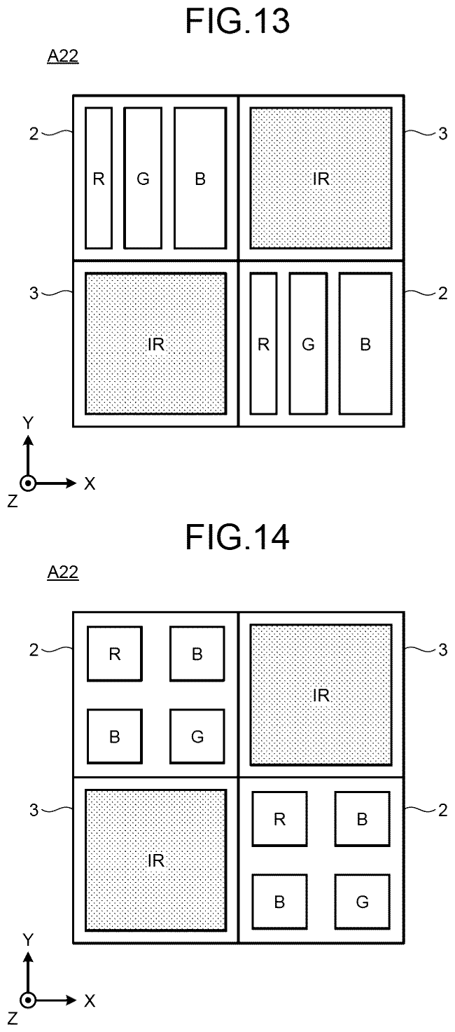

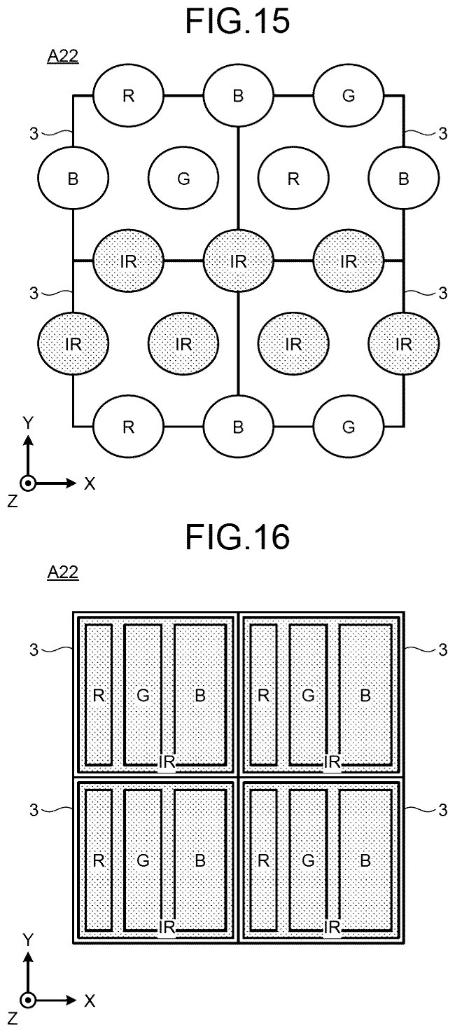

FIGS. 13 and 14 illustrate examples of a configuration of the display pixels 2 and the invisible light emitting pixels 3 that can be arranged in a mixed manner in the inner peripheral adjacent region A22. For example, the invisible light emitting pixels 3 are arranged in a portion obtained by thinning out the display pixels 2. The invisible light emitting pixel 3 emits only invisible light.

In the example illustrated in FIG. 13, each sub-pixel is arranged in a stripe manner such that one display pixel 2 includes one sub-pixel R, one sub-pixel G, and one sub-pixel B. One invisible light emitting pixel 3 includes one sub-pixel IR. The invisible light emitting pixel 3 may be referred to as the sub-pixel IR, and the sub-pixel IR may be referred to as the invisible light emitting pixel 3.

In the example illustrated in FIG. 14, each sub-pixel is arranged in a square manner such that one display pixel 2 includes one sub-pixel R, one sub-pixel G, and two sub-pixels B. One invisible light emitting pixel 3 includes one sub-pixel IR.

FIG. 15 illustrates an example of the configuration of the invisible light emitting pixels 3 that can be arranged in the inner peripheral adjacent region A22. In this example, each sub-pixel is arranged in a honeycomb manner such that one invisible light emitting pixel 3 includes one or more sub-pixels R, one or more sub-pixels G, one or more sub-pixels B, and one or more sub-pixels IR. The invisible light emitting pixel 3 emits not only invisible light but also visible light. The number of sub-pixels IR to be arranged is larger than that in FIG. 12 described above. Note that, in this honeycomb arrangement, there may be a display pixel 2 that does not include the sub-pixel IR. In this case, the display pixels 2 and the invisible light emitting pixels 3 are arranged in a mixed manner in the inner peripheral adjacent region A22.

FIGS. 16 to 18 illustrate examples of a configuration of the invisible light emitting pixels 3 that can be arranged in the inner peripheral adjacent region A22. In this example, the sub-pixel IR is arranged so as to overlap the sub-pixel R, the sub-pixel G, and the sub-pixel B. The invisible light emitting pixel 3 emits not only invisible light but also visible light.

In the example illustrated in FIG. 16, one invisible light emitting pixel 3 includes one sub-pixel R, one sub-pixel G, one sub-pixel B, and one sub-pixel IR. One sub-pixel R, one sub-pixel G, and one sub-pixel B are arranged in stripes. The sub-pixel IR is arranged so as to overlap with the sub-pixel R, the sub-pixel G, and the sub-pixel B.

In the example illustrated in FIG. 17, one invisible light emitting pixel 3 includes one sub-pixel R, one sub-pixel G, two sub-pixels B, and one sub-pixel IR. One sub-pixel R, one sub-pixel G, and two sub-pixels B are arranged in a square manner. The sub-pixel IR is arranged so as to overlap with the sub-pixel R, the sub-pixel G, and the sub-pixels B.

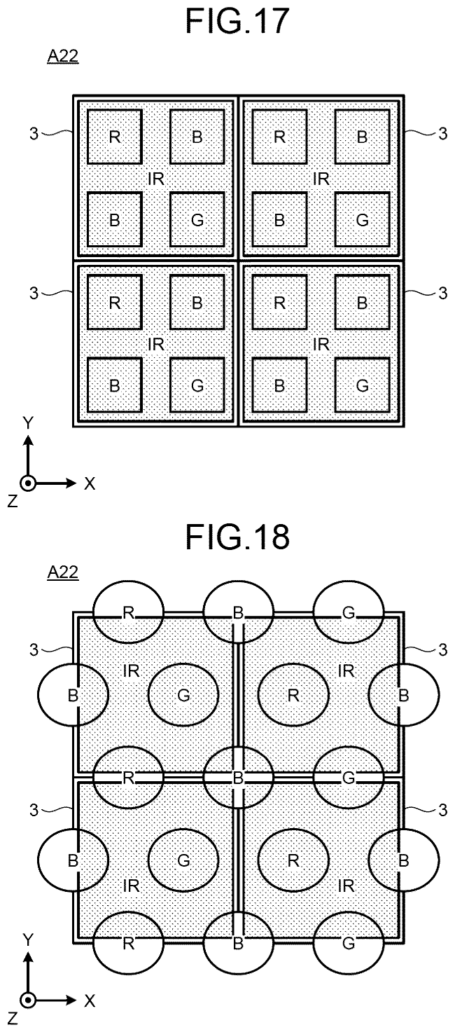

In the example illustrated in FIG. 18, one invisible light emitting pixel 3 includes one or more sub-pixels R, one or more sub-pixels G, one or more sub-pixels B, and one sub-pixel IR. The sub-pixel R, the sub-pixel G, and the sub-pixel B are arranged in a honeycomb arrangement. The sub-pixel IR is arranged so as to overlap at least a part of the sub-pixel R, the sub-pixel G, and the sub-pixel B.

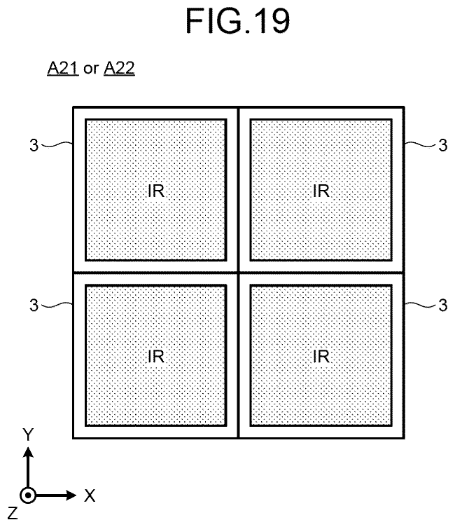

FIG. 19 illustrates an example of a configuration of the invisible light emitting pixels 3 that can be arranged in the outer peripheral adjacent region A21 or the inner peripheral adjacent region A22. One invisible light emitting pixel 3 includes one sub-pixel IR. The invisible light emitting pixel 3 emits only invisible light.

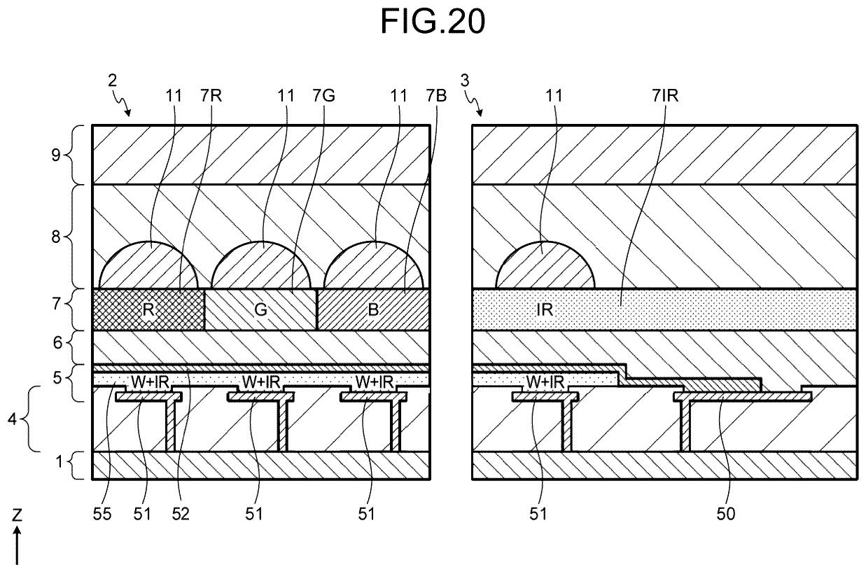

FIGS. 20 to 36 schematically illustrate a pixel configuration in a cross-sectional view (when viewed in a direction orthogonal to the Z-axis direction). Note that R, G, B, and IR letters are illustrated in association with red light, green light, blue light, and infrared light. In relation to white light, the letter W is illustrated. White light may be understood to mean light including red light, green light, and blue light. In connection with ultraviolet light, the letter UV is illustrated.

Various known laminated structures may be employed. An example illustrates a laminated structure including an insulating layer 4, a light emitting element layer 5, a protective layer 6, a filter layer 7, a resin layer 8, and a glass layer 9 laminated on a substrate 1. Various known materials may be used as a layer material unless otherwise specified.

The insulating layer 4 is provided on the substrate 1. The light emitting element layer 5 is provided on the insulating layer 4 so as to be electrically separated from the substrate 1 except for an electrode (first electrode 51 or the like) described later. Details of the light emitting element layer 5 will be described later. The protective layer 6 is provided on the light emitting element layer 5 so as to cover the light emitting element layer 5. The protective layer 6 may be formed of a material having a high refractive index. The protective layer 6 may be formed of, for example, a nitride film such as silicon nitride (SiN), a transparent conductive film such as indium tin oxide (ITO), indium zinc oxide (IZO), or zinc oxide (ZnO), or a transparent organic film. The protective layer 6 may be formed of an oxide film such as silicon oxide (SiO₂) or aluminum oxide (Al₂O₃), a resin film, or a cavity that is air (air gap).

The filter layer 7 is provided on a side opposite to the light emitting element layer 5 with the protective layer 6 interposed therebetween. The filter layer 7 may include a filter provided for each sub-pixel. The filter provided in the sub-pixel R is referred to as a filter 7R in the drawing. The filter 7R allows red light to pass therethrough. The filter provided in the sub-pixel G is referred to as a filter 7G in the drawing. The filter 7G allows green light to pass therethrough. The filter provided in the sub-pixel B is referred to as a filter 7B in the drawing. The filter 78 allows blue light to pass therethrough. The filter 7R, the filter 7G, and the filter 7B can also be referred to as color filters. The filter provided in the sub-pixel IR is referred to as a filter 7IR in the drawing. The filter 7IR allows infrared light to pass therethrough. The filter 7IR does not pass red light, green light, and blue light, and in this sense, the filter 7IR can also be referred to as a visible light cut filter arranged in the adjacent region A2. The filter layer 7 can be formed of, for example, a material in which a pigment or a dye is dispersed in a transparent binder such as silicone.

A lens 11 is provided on the filter layer 7 (on the Z-axis positive direction side). The lens 11 is a microlens provided corresponding to each of the sub-pixel R, the sub-pixel G, the sub-pixel B, and the sub-pixel IR, and can also be referred to as an on-chip lens or the like. For example, the lens 11 condenses light of the corresponding sub-pixel. The lens 11 can be formed of, for example, a styrene resin, an acrylic resin, a styrene-acrylic copolymer resin, or a siloxane resin.

The resin layer 8 is provided on the filter layer 7 so as to cover the lens 11. The glass layer 9 is provided on the resin layer 8.

The light emitting element layer 5 will be described. The light emitting element layer 5 includes a light emitting element. Examples of the light emitting element include an organic light emitting diode (OLED) and a light emitting diode (LED). The material of the OLED may be an organic fluorescent material or an organic phosphorescent material. The organic fluorescent material may be a thermally activated delayed fluorescence (TADF) material. A TADF-assisted fluorescent (TAF) mechanism may be employed. Examples of the LED may be a quantum dot (QD) LED or a Perovskite LED.

As an element related to the light emitting element, the light emitting element layer 5 includes a common electrode 50, a first electrode 51, a second electrode 52, and a light emitting layer 55.

The common electrode 50 may be arranged in the common peripheral region A3 (FIGS. 1 to 6) described above. The common electrode 50 is electrically connected to the substrate 1 so as to have a reference potential. The common electrode 50 and the substrate 1 are connected to each other via, for example, a via. The same applies to the first electrode 51, the second electrode 52, and the like.

The first electrode 51 is electrically connected to the lower surface (the surface on a Z-axis negative direction side) of the light emitting layer 55, and is electrically connected to the substrate 1. The first electrode 51 is provided in each of the sub-pixel R, the sub-pixel G, and the sub-pixel B of the display pixel 2, and the invisible light emitting pixel 3 (sub-pixel IR). For example, the first electrode 51 can function as an anode electrode. The first electrode 51 may also have a function as a reflection layer, and is preferably formed of a metal film having as a high reflectance as possible and a large work function in order to enhance light extraction efficiency. Examples of this metal film include a metal film containing at least one of a simple substance and an alloy of metal elements such as chromium (Cr), gold (Au), platinum (Pt), nickel (Ni), copper (Cu), molybdenum (Mo), titanium (Ti), tantalum (Ta), aluminum (Al), magnesium (Mg), iron (Fe), tungsten (W), and silver (Ag). Specific examples of the above alloy include an aluminum (Al) alloy such as an AlNi alloy or an AlCu alloy, and a silver (Ag) alloy such as an MgAg alloy. Further, the first electrode 51 may be formed of a transparent conductive film such as the indium tin oxide (ITO), indium zinc oxide (IZO), or zinc oxide (ZnO).

The second electrode 52 is electrically connected to the upper surface (the surface in the positive Z-axis direction) of the light emitting element layer 5, and is electrically connected to the common electrode 50. For example, the second electrode 52 may function as a cathode electrode. The second electrode 52 is a transparent electrode having transparency to light generated in the light emitting layer 55, and in the following description, the transparent electrode also includes a semi-transparent electrode. The second electrode 52 can be formed of a metal film containing at least one of a simple substance and an alloy of a metal element such as aluminum (Al), magnesium (Mg), calcium (Ca), sodium (Na), or silver (Ag). Specific examples of the alloy include an aluminum (Al) alloy such as an MgAg alloy or an AlLi alloy, and a silver (Ag) alloy. Further, the second electrode 52 may be formed of a transparent conductive film such as indium tin oxide (ITO), indium zinc oxide (IZO), or zinc oxide (ZnO).

The light emitting layer 55 is electrically connected between the first electrode 51 and the second electrode 52. When the light emitting element is the OLED, the light emitting layer 55 may be an organic material layer electrically connected between the anode and the cathode. When the light emitting element is the LED, the light emitting layer 55 may be an inorganic material layer electrically connected between the anode and the cathode.

FIGS. 20 to 26 illustrate examples of a pixel configuration when the light emitting element is the OLED.

In the example illustrated in FIG. 20, the display pixel 2 and the invisible light emitting pixel 3 commonly include a light emitting layer 55 that emits visible light and infrared light. In this example, the visible light emitted by the light emitting layer 55 is white light. The light emitting layer 55 has, for example, a laminated structure in which an organic material layer that emits white light and an organic material layer that emits infrared light are laminated.

The display pixel 2 includes a filter that allows white light from the light emitting layer 55 and visible light in infrared light to pass therethrough. In this example, the filter 7R, the filter 7G, and the filter 7B. The invisible light emitting pixel 3 (may also be the sub-pixel IR) includes a filter 7IR that allows white light from the light emitting layer 55 and infrared light in infrared light to pass therethrough. In the sub-pixel R of the display pixel 2, the white light from the light emitting layer 55 and the red light in the infrared light pass through the filter 7R. In the sub-pixel G, the green light passes through the filter 7G. In the sub-pixel B, the blue light passes through the filter 7B. In the invisible light emitting pixel 3, the infrared light passes through the filter 7IR. The light having passed through each filter passes through the lens 11 and is output.

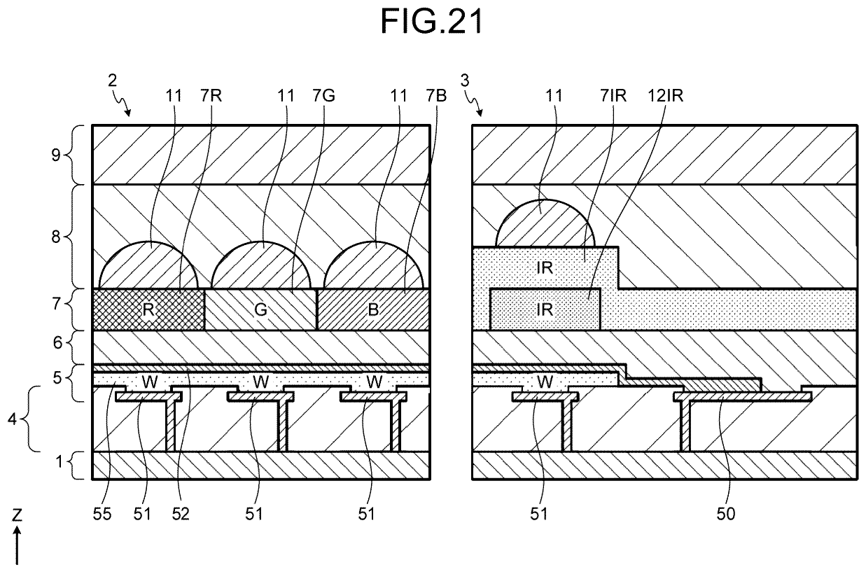

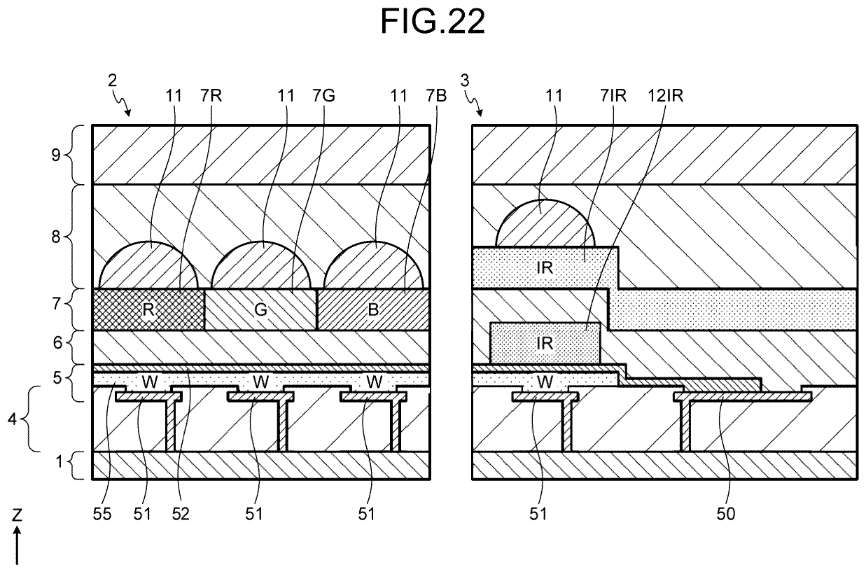

In the examples illustrated in FIGS. 21 and 22, the display pixel 2 and the invisible light emitting pixel 3 commonly include the light emitting layer 55 that emits visible light. In this example, the visible light emitted by the light emitting layer 55 is white light. The display pixel 2 includes a filter that allows visible light in the white light from the light emitting layer 55 to pass therethrough. In this example, the filter 7R, the filter 7G, and the filter 7B. The invisible light emitting pixel 3 includes a wavelength conversion layer 12IR. The wavelength conversion layer 12IR converts the white light from the light emitting layer 55 into infrared light. The wavelength conversion layer 12IR can also be referred to as a color conversion layer or the like. The wavelength conversion layer 12IR may be a quantum dot color converter (QDCC) layer.

The wavelength conversion layer 12IR may be provided on an upper portion (Z-axis positive direction side) of the protective layer 6 as illustrated in FIG. 21, or may be provided on a lower portion (Z-axis negative direction side) of the protective layer 6 as illustrated in FIG. 22. In the sub-pixel R of the display pixel 2, the red light in the white light from the light emitting layer 55 passes through the filter 7R. In the sub-pixel G, the green light passes through the filter 7G. In the sub-pixel B, the blue light passes through the filter 7B. In the invisible light emitting pixel 3, the infrared light from the wavelength conversion layer 12IR passes through the filter 7IR. The light having passed through each filter passes through the corresponding lens 11 and is output.

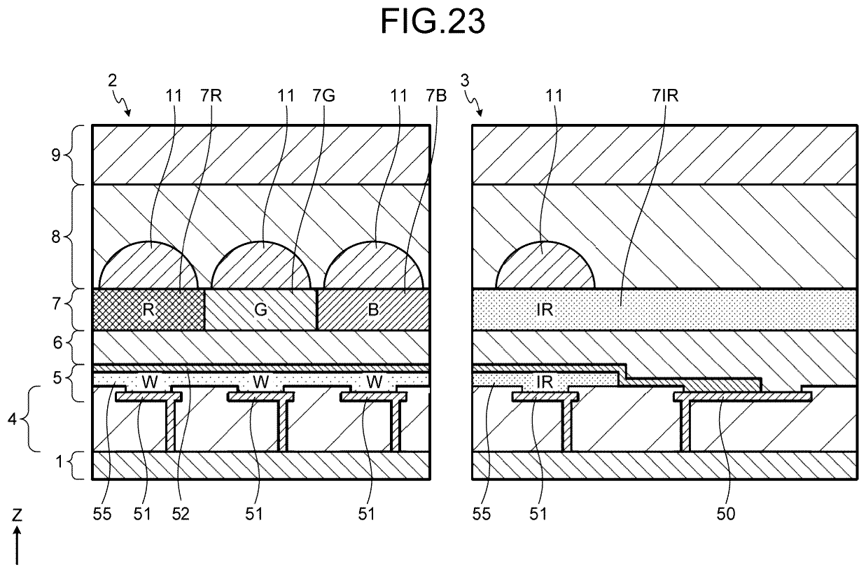

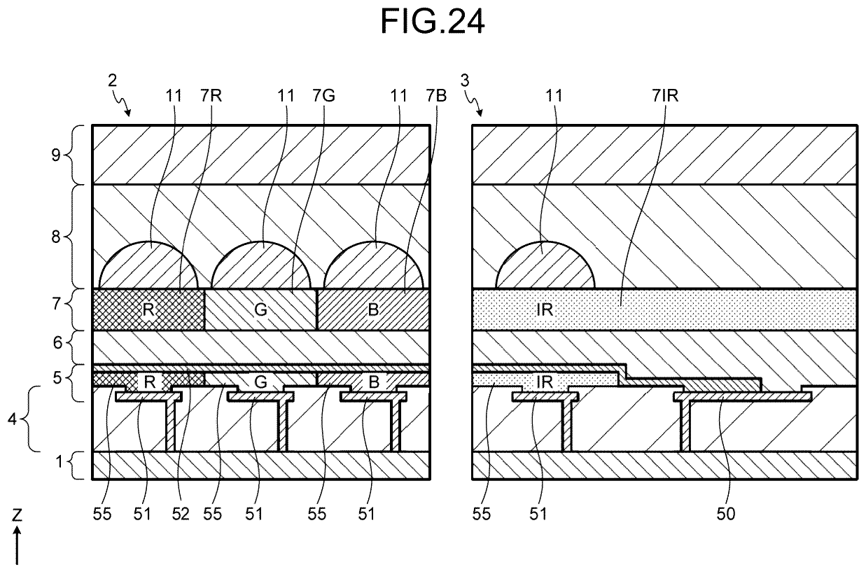

In the example illustrated in FIGS. 23 and 24, the light emitting layer 55 emits visible light in the display pixel 2 and emits infrared light in the invisible light emitting pixel 3. In other words, the display pixel 2 includes the light emitting layer 55 that emits visible light. The invisible light emitting pixel 3 includes the light emitting layer 55 that emits infrared light.

In the example illustrated in FIG. 23, the visible light emitted from the light emitting layer 55 is white light. The sub-pixel R, the sub-pixel G, and the sub-pixel B of the display pixel 2 commonly include the light emitting layer 55 that emits the white light. In the sub-pixel R of the display pixel 2, the red light in the white light from the light emitting layer 55 passes through the filter 7R. In the sub-pixel G, the green light passes through the filter 7G. In the sub-pixel B, the blue light from the light emitting layer 55 passes through the filter 7B. In the invisible light emitting pixel 3, the infrared light from the light emitting layer 55 passes through the filter 7IR. The light having passed through each filter passes through the corresponding lens 11 and is output.

In the example illustrated in FIG. 24, the light emitting layer 55 emits red light in the sub-pixel R of the display pixel 2, emits green light in the sub-pixel G, emits blue light in the sub-pixel B, and emits infrared light in the invisible light emitting pixel 3. In other words, the sub-pixel R of the display pixel 2 includes the light emitting layer 55 that emits red light. The sub-pixel G includes the light emitting layer 55 that emits green light. The sub-pixel B includes the light emitting layer 55 that emits blue light. The invisible light emitting pixel 3 includes the light emitting layer 55 that emits infrared light. In the sub-pixel R of the display pixel 2, the red light from the light emitting layer 55 passes through the filter 7R. In the sub-pixel G, the green light from the light emitting layer 55 passes through the filter 7G. In the sub-pixel B, the blue light from the filter 7B passes through the filter 7B. In the invisible light emitting pixel 3, the infrared light from the light emitting layer 55 passes through the filter 7IR. The light having passed through each filter passes through the corresponding lens 11 and is output.

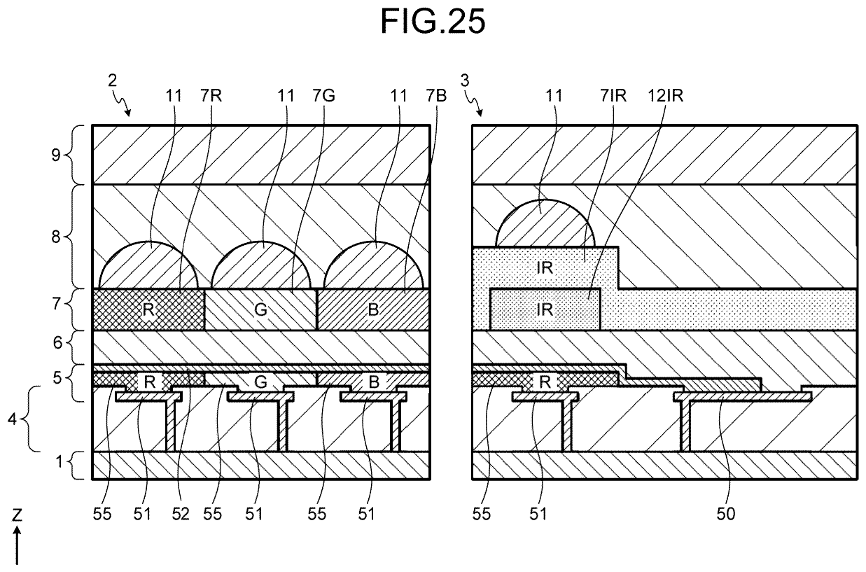

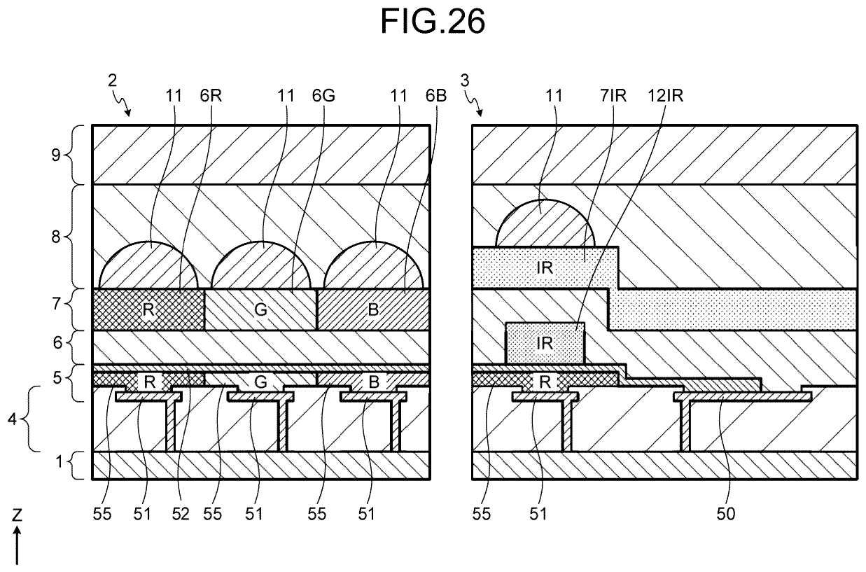

In the example illustrated in FIGS. 25 and 26, the light emitting layer 55 emits visible light in both the display pixel 2 and the invisible light emitting pixel 3. In other words, the display pixel 2 and the invisible light emitting pixel 3 include the light emitting layer 55 that emits visible light. In this example, the light emitting layer 55 emits red light in the sub-pixel R of the display pixel 2, emits green light in the sub-pixel G, emits blue light in the sub-pixel B, and emits red light in the invisible light emitting pixel 3. In other words, the sub-pixel R of the display pixel 2 includes the light emitting layer 55 that emits red light. The sub-pixel G includes the light emitting layer 55 that emits green light. The sub-pixel B includes the light emitting layer 55 that emits blue light. The invisible light emitting pixel 3 includes the light emitting layer 55 that emits infrared light. In addition, the invisible light emitting pixel 3 includes the wavelength conversion layer 12IR. Here, the wavelength conversion layer 12IR converts the red light from the light emitting layer 55 into infrared light.

The wavelength conversion layer 12IR may be provided on an upper portion (Z-axis positive direction side) of the protective layer 6 as illustrated in FIG. 25, or may be provided on a lower portion (Z-axis negative direction side) of the protective layer 6 as illustrated in FIG. 26. In the sub-pixel R of the display pixel 2, the red light from the light emitting layer 55 passes through the filter 7R. In the sub-pixel G of the display pixel 2, the green light from the light emitting layer 55 passes through the filter 7G. In the sub-pixel B of the display pixel 2, the blue light from the light emitting layer 55 passes through the filter 7B. In the invisible light emitting pixel 3, the infrared light from the wavelength conversion layer 12IR passes through the filter 7IR. The light having passed through each filter passes through the corresponding lens 11 and is output.

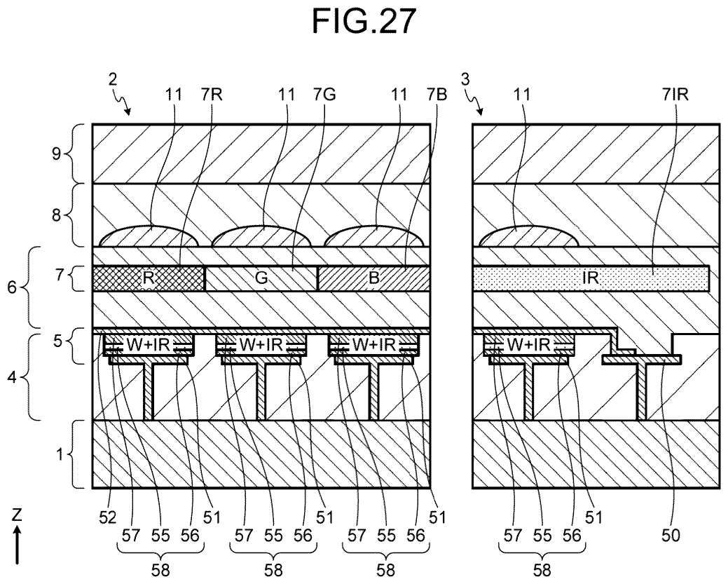

FIGS. 27 to 32 illustrate examples of a pixel configuration when the light emitting element is the LED. The light emitting layer 55 is a light emitting layer of an LED58. The LED58 is provided in each of the sub-pixel R, the sub-pixel G, and the sub-pixel B of the display pixel 2, and the invisible light emitting pixel 3. As components of the LED58, in addition to the light emitting layer 55, an anode 56 and a cathode 57 are also illustrated. The anode 56 is electrically connected between the light emitting layer 55 and the first electrode 51. The cathode 57 is electrically connected between the light emitting layer 55 and the second electrode 52.

In the example illustrated in FIG. 27, the light emitting layer 55 emits visible light and infrared light. In this example, the visible light emitted by the light emitting layer 55 is white light. In other words, each of the sub-pixel R, the sub-pixel G, the sub-pixel B, and the sub-pixel IR includes the light emitting layer 55 that emits white light and infrared light. In the sub-pixel R of the display pixel 2, the white light from the light emitting layer 55 and the red light in the infrared light pass through the filter 7R. In the sub-pixel G, the green light passes through the filter 7G. In the sub-pixel B, the blue light passes through the filter 7B. In the invisible light emitting pixel 3, the infrared light passes through the filter 7IR. The light having passed through each filter passes through the corresponding lens 11 and is output.

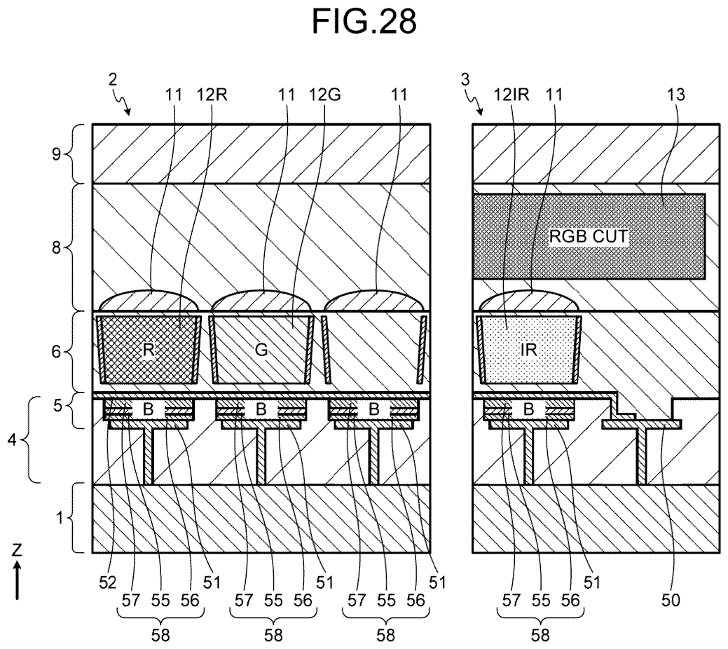

In the example illustrated in FIGS. 28 and 29, the sub-pixel R, the sub-pixel G, and the sub-pixel B of the display pixel 2 include the light emitting layer 55 that emits visible light. In this example, the visible light is blue light. The sub-pixel R includes a wavelength conversion layer 12R. The wavelength conversion layer 12R converts the blue light from the light emitting layer 55 into red light. The sub-pixel G includes a wavelength conversion layer 12G. The wavelength conversion layer 12G converts the blue light from the light emitting layer 55 into green light. The invisible light emitting pixel 3 includes a visible light cut filter 13. The visible light cut filter 13 does not pass (attenuates) visible light, for example, red light, green light, and blue light, but passes infrared light. The visible light cut filter 13 may have the same configuration as the filter 7IR, and may be arranged in the adjacent region A2 similarly to the filter 7IR. In this example, visible light cut filter 13 is provided above lens 11 (on the Z-axis positive direction side).

In the example illustrated in FIG. 28, the invisible light emitting pixel 3 includes the light emitting layer 55 that emits blue light, similarly to the sub-pixel R, the sub-pixel G, and the sub-pixel B of the display pixel 2. The invisible light emitting pixel 3 also includes the wavelength conversion layer 12IR. Here, the wavelength conversion layer 12IR converts the blue light from the light emitting layer 55 into infrared light. In the sub-pixel R of the display pixel 2, the red light from the wavelength conversion layer 12R passes through the corresponding lens 11 and is output. In the sub-pixel G, the green light from the wavelength conversion layer 12G passes through the corresponding lens 11 and is output. In the sub-pixel B, the blue light from the light emitting layer 55 passes through the corresponding lens 11 and is output. In the invisible light emitting pixel 3, the infrared light from the wavelength conversion layer 12IR passes through the corresponding lens 11, passes through the visible light cut filter 13, and is output.

In the example illustrated in FIG. 29, the invisible light emitting pixel 3 includes the light emitting layer 55 that emits infrared light. In the sub-pixel R of the display pixel 2, the red light from the wavelength conversion layer 12R passes through the corresponding lens 11 and is output. In the sub-pixel G, the green light from the wavelength conversion layer 12G passes through the corresponding lens 11 and is output. In the sub-pixel B, the blue light from the light emitting layer 55 passes through the corresponding lens 11 and is output. In the invisible light emitting pixel 3, the infrared light from the light emitting layer 55 passes through the corresponding lens 11, passes through the visible light cut filter 13, and is output.

In FIGS. 28 and 29, the visible light emitted from light emitting layer 55 may be red light or green light. Some sub-pixels of the sub-pixel R, the sub-pixel G, and the sub-pixel B, more specifically, sub-pixels that do not correspond to the visible light emitted by the light emitting layer 55 may include a wavelength conversion layer that converts the visible light from the light emitting layer 55 into a color corresponding to each of the sub-pixels.

In the example illustrated in FIG. 30, the display pixel 2 and the invisible light emitting pixel 3 include the light emitting layer 55 that emits visible light. In this example, the sub-pixel R of the display pixel 2 includes the light emitting layer 55 that emits red light. The sub-pixel G includes the light emitting layer 55 that emits green light. The sub-pixel B includes the light emitting layer 55 that emits blue light. The invisible light emitting pixel 3 includes the light emitting layer 55 that emits red light. The invisible light emitting pixel 3 also includes the wavelength conversion layer 12IR and the visible light cut filter 13. Here, the wavelength conversion layer 12IR converts the red light from the light emitting layer 55 into infrared light. In the sub-pixel R of the display pixel 2, the red light from the light emitting layer 55 passes through the corresponding lens 11 and is output. In the sub-pixel G, the green light from the light emitting layer 55 passes through the corresponding lens 11 and is output. In the sub-pixel B, the blue light from the light emitting layer 55 passes through the corresponding lens 11 and is output. In the invisible light emitting pixel 3, the infrared light from the wavelength conversion layer 12IR passes through the corresponding lens 11, passes through the visible light cut filter 13, and is output.

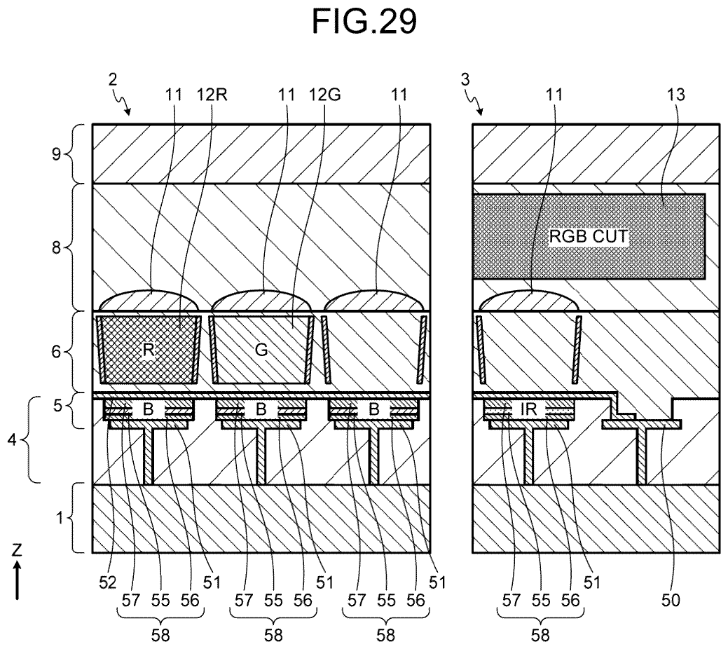

In the example illustrated in FIG. 31, the display pixel 2 includes the light emitting layer 55 that emits visible light. In this example, the sub-pixel R of the display pixel 2 includes the light emitting layer 55 that emits red light. The sub-pixel G includes the light emitting layer 55 that emits green light. The sub-pixel B includes the light emitting layer 55 that emits blue light. The invisible light emitting pixel 3 includes the light emitting layer 55 that emits infrared light. The invisible light emitting pixel 3 also includes the visible light cut filter 13. In this example, the visible light cut filter 13 is provided below lens 11 (on the Z-axis negative direction side). In the sub-pixel R of the display pixel 2, the red light from the light emitting layer 55 passes through the corresponding lens 11 and is output. In the sub-pixel G, the green light from the light emitting layer 55 passes through the corresponding lens 11 and is output. In the sub-pixel B, the blue light from the light emitting layer 55 passes through the corresponding lens 11 and is output. In the invisible light emitting pixel 3, the infrared light from the light emitting layer 55 passes through the visible light cut filter 13, passes through the lens 11, and is output.

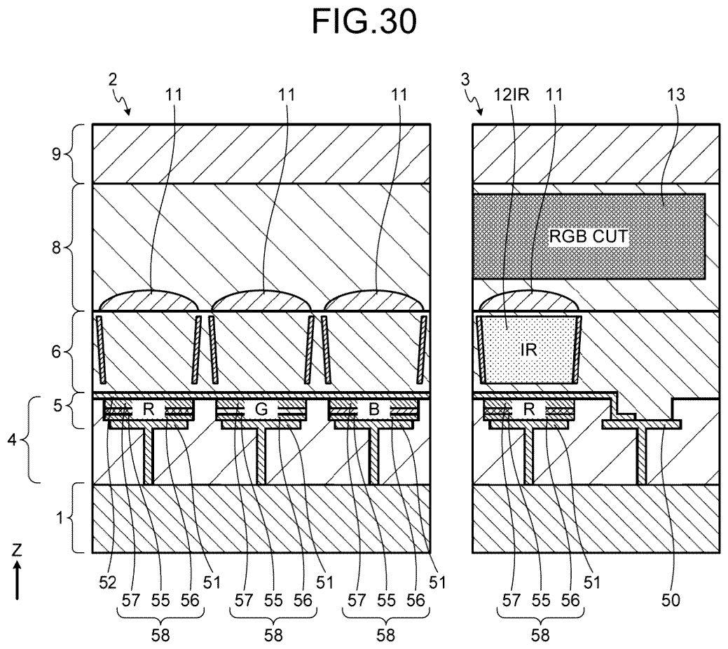

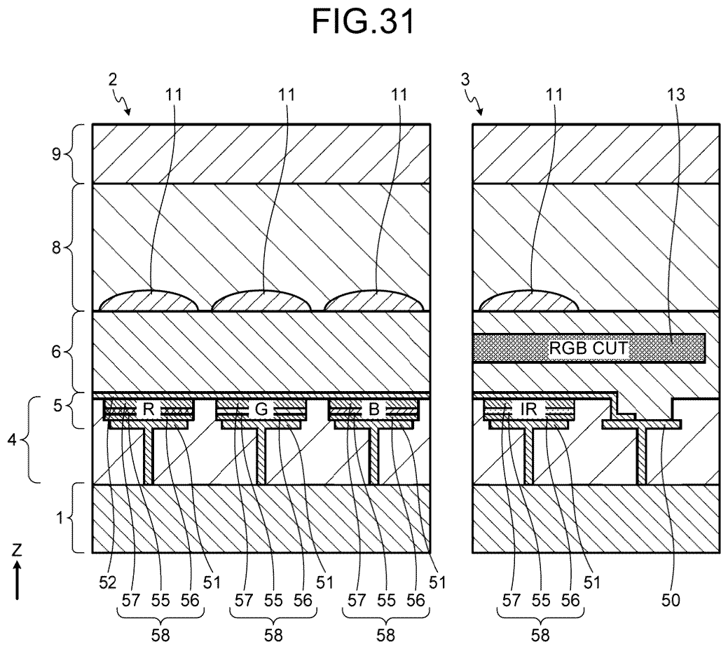

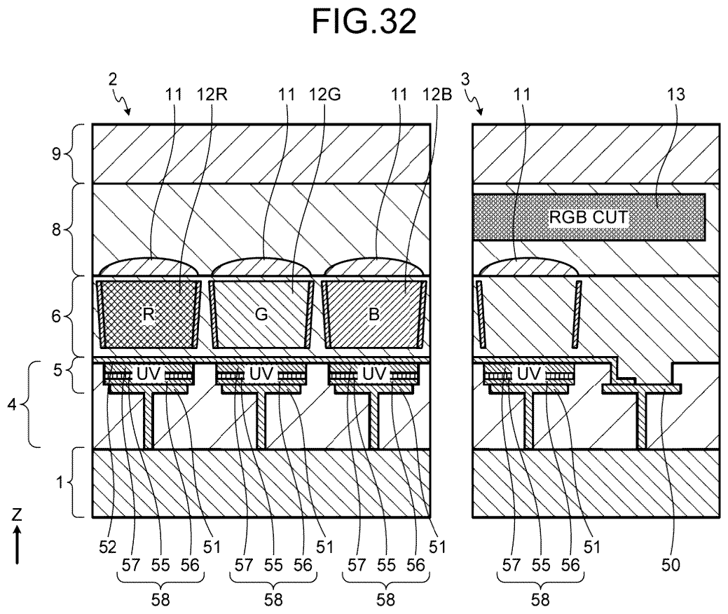

In the example illustrated in FIG. 32, the display pixel 2 and the invisible light emitting pixel 3 include the light emitting layer 55 that emits invisible light. In this example, the invisible light is ultraviolet light. The sub-pixel R of the display pixel 2 includes the wavelength conversion layer 12R. Here, the wavelength conversion layer 12R converts the ultraviolet light from the light emitting layer 55 into red light. The sub-pixel G includes the wavelength conversion layer 12G. Here, the wavelength conversion layer 12G converts the ultraviolet light from the light emitting layer 55 into green light. The sub-pixel B includes a wavelength conversion layer 12B. The wavelength conversion layer 12B herein converts the ultraviolet light from the light emitting element layer 5 into blue light. The invisible light emitting pixel 3 includes the visible light cut filter 13. In the sub-pixel R of the display pixel 2, the red light from the wavelength conversion layer 12R passes through the corresponding lens 11 and is output. In the sub-pixel G, the green light from the wavelength conversion layer 12G passes through the corresponding lens 11 and is output. In the sub-pixel B, the blue light from the wavelength conversion layer 12B passes through the corresponding lens 11 and is output. In the invisible light emitting pixel 3, the ultraviolet light from the light emitting layer 55 passes through the lens 11, passes through the visible light cut filter 13, and is output.

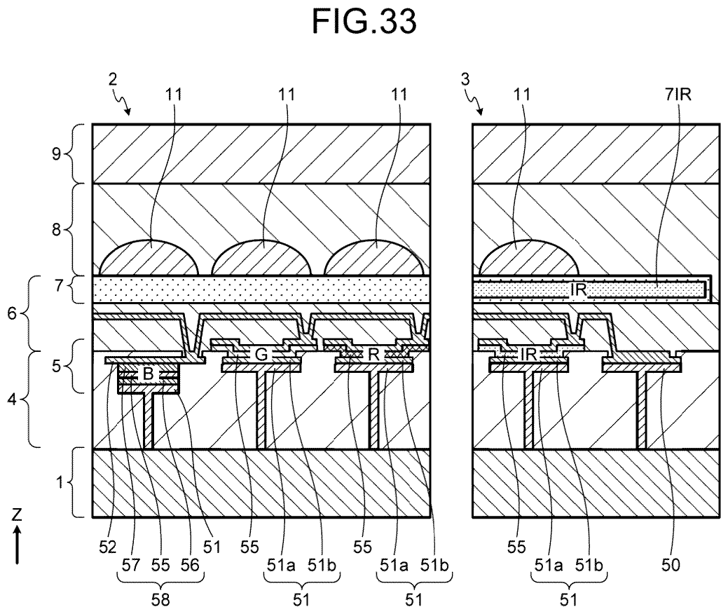

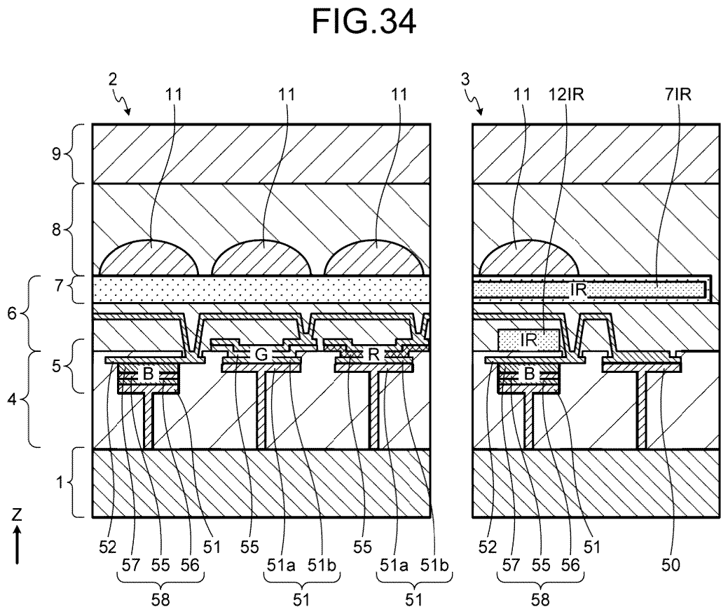

FIGS. 33 and 34 illustrate examples of a pixel configuration when the OLED and the LED are provided as light emitting elements in a mixed manner.

In the example illustrated in FIG. 33, the sub-pixel B of the display pixel 2 includes the light emitting layer 55 of the LED58 that emits blue light. The sub-pixel G includes the light emitting layer 55 of the OLED that emits green light. The sub-pixel R includes the light emitting layer 55 of the OLED that emits red light. The invisible light emitting pixel 3 includes the light emitting layer 55 of the OLED that emits infrared light. The invisible light emitting pixel 3 also includes the filter 7IR. In this example, the first electrode 51 of the OLED has a two-layer configuration in which an electrode 51a and an electrode 51b are laminated. The electrode 51b is electrically connected between the electrode 51a and the light emitting layer 55. An example of a material of the electrode 51a is a light reflecting material such as aluminum. An example of a material of the electrode 51b is a light transmitting material such as ITO. In the sub-pixel B of the display pixel 2, the blue light from the light emitting layer 55 passes through the corresponding lens 11 and is output. In the sub-pixel G, the green light from the light emitting layer 55 passes through the corresponding lens 11 and is output. In the sub-pixel R, the red light from the light emitting layer 55 passes through the corresponding lens 11 and is output. In the invisible light emitting pixel 3, the infrared light from the light emitting layer 55 passes through the filter 7IR, passes through the lens 11, and is output.

In the example illustrated in FIG. 34, the sub-pixel B of the display pixel 2 includes the light emitting layer 55 of the LED58 that emits blue light. The sub-pixel G includes the light emitting layer 55 of the OLED that emits green light. The sub-pixel R includes the light emitting layer 55 of the OLED that emits red light. The invisible light emitting pixel 3 includes the light emitting layer 55 of the LED58 that emits blue light. The invisible light emitting pixel 3 also includes the wavelength conversion layer 12IR and the filter 7IR. In the sub-pixel B of the display pixel 2, the blue light from the light emitting layer 55 passes through the corresponding lens 11 and is output. In the sub-pixel G, the green light from the light emitting layer 55 passes through the corresponding lens 11 and is output. In the sub-pixel R, the red light from the light emitting layer 55 passes through the corresponding lens 11 and is output. In the invisible light emitting pixel 3, the infrared light from the wavelength conversion layer 12IR passes through the filter 7IR, passes through the lens 11, and is output.

FIG. 35 illustrates the invisible light emitting pixel 3 that emits invisible light and visible light. As illustrated on the right side of (A) of FIG. 35, the invisible light emitting pixel 3 includes the sub-pixel R, the sub-pixel G, the sub-pixel B, and the sub-pixel IR. For example, as illustrated in FIGS. 16 to 18 described above, the sub-pixel IR is arranged so as to overlap the sub-pixel R, the sub-pixel G, and the sub-pixel B.

In this example, the light emitting element is the OLED. The display pixel 2 and the invisible light emitting pixel 3 commonly include the light emitting layer 55 that emits visible light. In this example, the visible light emitted by the light emitting layer 55 is white light. The invisible light emitting pixel 3 also includes a light emitting layer 55-2 and a third electrode 53, and has a laminated structure in which the light emitting layer 55, the light emitting layer 55-2, and the like are laminated. The light emitting layer 55-2 emits infrared light. The light emitting layer 55-2 is provided on a side opposite to the light emitting layer 55 across the second electrode 52. The third electrode 53 is electrically connected to an upper surface (surface in the Z-axis positive direction) of the light emitting layer 55-2, and is electrically connected to an infrared light electrode 54, for example, as illustrated in (B) of FIG. 35. (B) of FIG. 35 illustrates a pixel configuration in a cross-sectional view from a direction different from (A) of FIG. 34. The infrared light electrode 54 is electrically connected to the substrate 1. The infrared light electrode 54 can be arranged in the common peripheral region A4 (FIGS. 4 to 6) described above.

The invisible light emitting pixel 3 includes a filter 7BIR, a filter 7GIR, a filter 7RIR, and the filter 7IR. The filter 7BIR is provided in the sub-pixel B of the invisible light emitting pixel 3, and allows the white light from the light emitting layer 55 and the blue light and the infrared light in the infrared light from the light emitting layer 55-2 to pass therethrough. The filter 7GIR is provided in the sub-pixel G of the invisible light emitting pixel 3, and allows the white light from the light emitting layer 55 and the green light and the infrared light in the infrared light from the light emitting layer 55-2 to pass therethrough. The filter 7RIR is provided in the sub-pixel R of the invisible light emitting pixel 3, and allows the white light from the light emitting layer 55 and the red light in the infrared light from the light emitting layer 55-2 to pass therethrough.

In the sub-pixel R of the display pixel 2, the red light in the white light from the light emitting layer 55 passes through the filter 7R. In the sub-pixel G, the green light passes through the filter 7G. In the sub-pixel B, the blue light passes through the filter 7B. In the sub-pixel B of the invisible light emitting pixel 3, the white light from the light emitting layer 55 and the blue light and the infrared light in the infrared light from the light emitting layer 55-2 pass through the filter 7BIR. In the sub-pixel G, the green light and the infrared light pass through the filter 7GIR. In the sub-pixel R, the red light and the infrared light pass through the filter 7RIR. The light having passed through each filter passes through the corresponding lens 11 and is output.

As illustrated in (C) of FIG. 35, the light emitting layer 55-2 may be provided so as to cover common electrode 50. It can also be said that the invisible light emitting pixel 3 has a laminated structure in which the light emitting layer 55, the light emitting layer 55-2, the common electrode 50, and the like are laminated. In addition, the lens 11 may be provided at a position corresponding to the common electrode 50. The infrared light from the light emitting layer 55-2 on the common electrode 50 passes through the filter 7IR, passes through the lens 11, and is output.

As illustrated in FIG. 36, the light emitting layer 55-2 may be provided so as to cover only the common electrode 50. In this example, the display pixel 2 includes the light emitting layer 55 that emits visible light, more specifically white light. The invisible light emitting pixel 3 includes the light emitting layer 55-2 that emits infrared light.

Note that the light emitting layer 55 in FIGS. 35 and 36 may emit white light and infrared light, or may emit red light, green light, and blue light. Any layer that emits at least visible light among visible light and invisible light may be used.

The display device 110 described above is used by being incorporated in, for example, an electronic apparatus. The electronic apparatus will be described with reference to FIGS. 37 and 38.

FIGS. 37 and 38 are diagrams illustrating examples of a schematic configuration of the electronic apparatus. An electronic apparatus 105 includes the display device 110 described above, an imaging device 120, and an optical element 130. A user of the electronic apparatus 105 is referred to as a user U in the drawing. FIGS. 37 and 38 schematically illustrate an eye portion of the user U. Unless otherwise specified, it is assumed that the user U is the eye portion of the user U.

The imaging device 120 images invisible light. For example, the imaging device 120 includes an image sensor or the like that detects invisible light.

The optical element 130 guides invisible light from the adjacent region A2 of the display device 110 to the user U, and guides invisible light reflected by the user U to the imaging device 120.

In the example illustrated in FIG. 37, the imaging device 120 is arranged in the vicinity of the display device 110. For example, when the display device 110 is viewed from the front (viewed in the Z-axis negative direction), at least a part of the imaging device 120 may overlap the edge of display device 110. The optical element 130 includes a lens 130a located between the display device 110 and the user U. The lens 130a may be a magnifying lens. The invisible light from the adjacent region A2 of the display device 110 passes through the lens 130a and is emitted to the user U. The invisible light reflected by the user U passes through the lens 130a and is applied to the imaging device 120. The user U is imaged by the imaging device 120.

For example, biological information such as the line of sight, iris, pupil, and blink of the user U may be acquired based on an imaging result of the imaging device 120. The biometric information acquired may be used for foveated rendering, a user interface (UI) such as a user operation by the line of sight, behavior analysis/support, biometric authentication, and the like.

In the example illustrated in FIG. 38, the imaging device 120 is arranged at a position away from the display device 110. For example, when the display device 110 is viewed from the front, the imaging device 120 may not overlap display device 110. The optical element 130 further includes a half mirror 130b located between the display device 110 and the lens 130a. The half mirror 130b guides a part of invisible light from the adjacent region A2 of the display device 110 to the lens 130a, and guides a part of invisible light from the lens 130a to the imaging device 120. The invisible light from the adjacent region A2 of the display device 110 passes through the half mirror 130b and the lens 130a and is emitted to the user U. The invisible light reflected by the user U passes through the lens 130a and the half mirror 130b and is emitted to the imaging device 120. The user U is imaged by the imaging device 120. Note that an optical element such as a prism may be used together with the half mirror 130b or instead of the half mirror 130b.

The optical element 130 may be configured to have a function of preventing reflection of the visible light and the invisible light. For example, an antireflection coating may be applied to the surface of the optical element 130.

### 2. MODIFIED EXAMPLES

The technology disclosed is not limited to the above embodiment. Some modified examples will be described.

The adjacent region A2 in which the invisible light emitting pixels 3 are arranged may be a region on an opposite side of a power supply terminal (FPD, COC, etc.) on the substrate 1. An influence of a voltage drop on the display region A1 can be reduced.

A pixel area of the invisible light emitting pixel 3 (sub-pixel IR) may be larger than a pixel area of the sub-pixel R, the sub-pixel B, or the sub-pixel G of the display pixel 2. As a result, the size (W length) of a transistor related to driving of the invisible light emitting pixels 3 or the like can be increased to increase a current amount.

Drive control of the display pixel 2 and the invisible light emitting pixel 3 may be common or individual. Refresh rates of the display pixel 2 and the invisible light emitting pixel 3 may be the same or different. Refreshing may or may not be synchronized.

A light emission period of the visible light by the display pixel 2 and a light emission period of the invisible light by the invisible light emitting pixel 3 may overlap or may not overlap. In the latter case, noise to the imaging device 120 due to light in the display region A1 can be reduced.

The display pixel 2 and the invisible light emitting pixel 3 may or may not be synchronized. In the latter case, disturbance of the captured image by the imaging device 120 can be reduced.

An arrangement and on/off of the invisible light emitting pixels 3 may be controlled to change an emission pattern of the invisible light.

The electrode of the light emitting element and the electrode of the invisible light emitting element may be common or individual. When voltages of the light emitting elements are different from each other, power consumption can be reduced by providing individual electrodes.

Each filter of the filter layer 7 may be formed of a resist or a dielectric multilayer film. The position of the filter may be shifted for each pixel (for each sub-pixel) in accordance with the optical element.

The lens 11 may be arranged only in one of the display pixel 2 and the invisible light emitting pixel 3, or may be arranged in both of the display pixel 2 and the invisible light emitting pixel 3. The position of the lens 11 may be shifted for each pixel (for each sub-pixel) according to the optical element.

### 3. EXAMPLES OF EFFECT

For example, the technology described above is specified as follows. One of the disclosed techniques is the display device 110. As described with reference to FIGS. 1 to 6 and the like, the display device 110 includes the display region A1 in which the display pixels 2 that emit visible light are arranged, and the adjacent region A2 adjacent to the display region A1 along the edge of the display region A1 and in which the invisible light emitting pixels 3 that emit at least invisible light in visible light and invisible light are arranged.

According to the display device 110 above, the invisible light emitting pixels 3 are arranged in the adjacent region A2 adjacent to the display region A1 along the edge of the display region A1. As a result, for example, it is possible to suppress an increase in the area of the substrate 1 and to suppress an increase in the size of the display device 110 as compared with a case where the invisible light emitting pixels 3 are arranged at positions distant from the display region A1. Furthermore, for example, as compared with a case where the invisible light emitting pixel 3 is arranged at a position away from the edge of the display region A1 in the display region A1, deterioration in display performance such as resolution and luminance can be suppressed.

As described with reference to FIGS. 1 to 6 and the like, the adjacent region A2 may include at least one of the outer peripheral adjacent region A21 that is at least a part of the outer peripheral region of the display region A1 and the inner peripheral adjacent region A22 that is at least a part of the inner peripheral region of the display region A1. For example, the invisible light emitting pixels 3 can be arranged in this adjacent region A2.

As described with reference to FIGS. 10 to 18 and the like, the invisible light emitting pixels 3 incorporating the function of the display pixels 2 (e.g., sub-pixel R, sub-pixel G, and sub-pixel B) may be arranged in the inner peripheral adjacent region A22. As a result, the effect of suppressing deterioration in display performance can be further enhanced.

As described with reference to FIG. 20 and the like, the display pixel 2 and the invisible light emitting pixel 3 may commonly include the light emitting layer 55 that emits visible light and invisible light (e.g., white light and infrared light), the display pixel 2 may include the filter (e.g., the filter 7R, the filter 7G, and the filter 7B) that passes visible light from the light emitting layer 55 and visible light in invisible light, and the invisible light emitting pixel 3 may include a filter (e.g., the filter 7IR) that passes visible light from the light emitting layer 55 and invisible light in invisible light. In this case, the display pixel 2 and the invisible light emitting pixel 3 can be obtained using the common light emitting layer 55.

As described with reference to FIGS. 21 and 22 and the like, the display pixel 2 and the invisible light emitting pixel 3 may commonly include the light emitting layer 55 that emits visible light (e.g., white light), the display pixel 2 may include the filter (e.g., the filter 7R, the filter 7G, and the filter 7B) that passes the visible light from the light emitting layer 55, and the invisible light emitting pixel 3 may include the wavelength conversion layer (e.g., the wavelength conversion layer 12IR) that converts the visible light from the light emitting layer 55 into invisible light (e.g., infrared light). In this case, the display pixel 2 and the invisible light emitting pixel 3 can be obtained using the common light emitting layer 55.

As described with reference to FIGS. 7 to 18, 28, and the like, the display pixel 2 may include the plurality of sub-pixels (e.g., the sub-pixel R, the sub-pixel G, and the sub-pixel B) corresponding to different colors, the plurality of sub-pixels and the invisible light emitting pixel 3 may include the light emitting layer 55 that emits visible light (e.g., blue light), some of the plurality of sub-pixels (e.g., sub-pixel R and sub-pixel G) may include the wavelength conversion layer (e.g., the wavelength conversion layer 12R and the wavelength conversion layer 12G) that converts the visible light from the light emitting layer 55 into light (e.g., red light and green light) of a color corresponding to the sub-pixel, and the invisible light emitting pixel 3 may include the wavelength conversion layer (e.g., the wavelength conversion layer 12IR) that converts the visible light from the light emitting layer 55 into invisible light (e.g., infrared light). In this case, the display pixel 2 and the invisible light emitting pixel 3 can be obtained using only the light emitting layer 55 that emits visible light of a specific color.

As described with reference to FIGS. 7 to 18, 29, and the like, the display pixel 2 may include the plurality of sub-pixels (e.g., the sub-pixel R, the sub-pixel G, and the sub-pixel B) corresponding to different colors, the plurality of sub-pixels may include the light emitting layer 55 that emits visible light (e.g., blue light), the invisible light emitting pixel 3 may include the light emitting layer 55 that emits invisible light (e.g., infrared light), and some sub-pixels of the plurality of sub-pixels may include the wavelength conversion layer (e.g., the wavelength conversion layer 12R and the wavelength conversion layer 12G) that converts the visible light from the light emitting layer 55 into a color (e.g., red light and green light) corresponding to the sub-pixel. In this case, the display pixel 2 can be obtained using only the light emitting layer 55 that emits visible light of a specific color, and the invisible light emitting pixel 3 can be obtained using the light emitting layer 55 that emits invisible light.

As described with reference to FIGS. 7 to 18, 23, 24, 31, and the like, the display pixel 2 may include the plurality of sub-pixels (e.g., the sub-pixel R, the sub-pixel G, and the sub-pixel B) corresponding to different colors, the plurality of sub-pixels may include the light emitting layer 55 (e.g., white light, or red light, green light, and blue light) that emits visible light and the filter (e.g., the filter 7R, the filter 7G, and the filter 7B) that passes the corresponding light (e.g., red light, green light, and blue light), and the invisible light emitting pixel 3 may include the light emitting layer 55 that emits invisible light (e.g., infrared light). In this way, the display pixel 2 and the invisible light emitting pixel 3 can also be obtained.

As described with reference to FIGS. 25, 26, 30, and the like, the display pixel 2 and the invisible light emitting pixel 3 may include the light emitting layer 55 that emits visible light (e.g., red light, green light, and blue light), and the invisible light emitting pixel 3 may include the wavelength conversion layer 12IR that converts visible light (e.g., red light) from the light emitting layer 55 into invisible light (e.g., infrared light). In this case, the display pixel 2 and the invisible light emitting pixel 3 can be obtained using only the light emitting layer 55 that emits visible light.

As described with reference to FIG. 32 and the like, the display pixel 2 and the invisible light emitting pixel 3 may include the light emitting layer 55 that emits invisible light (e.g., ultraviolet light), and the display pixel 2 may include the wavelength conversion layer (e.g., the wavelength conversion layer 12R, the wavelength conversion layer 12G, and the wavelength conversion layer 12B) that converts the invisible light from the light emitting layer 55 into visible light (e.g., red light, green light, and blue light). In this case, the display pixel 2 and the invisible light emitting pixel 3 can be obtained using only the light emitting layer 55 that emits invisible light.

As described with reference to FIGS. 4, 36, and the like, the adjacent region A2 may include the outer peripheral adjacent region A21 that is a part of the outer peripheral region of the display region A1, the outer peripheral region of the display region A1 may include the common peripheral region A3 (the common electrode region or the circuit region of the visible light emitting element) and the common peripheral region A4 (the common electrode region or the circuit region of the invisible light emitting element), and the outer peripheral adjacent region A21 in which the invisible light emitting pixels 3 are arranged may be the common peripheral region A3. As described with reference to FIGS. 5, 10 to 18, 35, and the like, the adjacent region A2 may include the inner peripheral adjacent region A22 that is a part of the inner peripheral region of the display region A1, the invisible light emitting pixel 3 in which the function of the display pixel 2 (e.g., sub-pixel R, sub-pixel G, and sub-pixel B) is incorporated may be arranged in the inner peripheral adjacent region A22, and the outer peripheral region of the display region A1 may include the common peripheral region A4 (common electrode region or circuit region of the invisible light emitting element). As described with reference to FIGS. 6, 10 to 18, 35, 36, and the like, the adjacent region A2 may include the outer peripheral adjacent region A21 that is a part of the outer peripheral region of the display region A1 and the inner peripheral adjacent region A22 that is a part of the inner peripheral region of the display region, the outer peripheral region of the display region A1 may include the common peripheral region A3 (the common electrode region or the circuit region of the visible light emitting element) and the common peripheral region A4 (the common electrode region or the circuit region of the invisible light emitting element), the outer peripheral adjacent region A21 in which the invisible light emitting pixels 3 are arranged may be the common peripheral region A3 (the common electrode region or the circuit region of the visible light emitting element), and the invisible light emitting pixels 3 incorporating the function of the display pixels 2 (e.g., sub-pixel R, sub-pixel G, and sub-pixel B) may be arranged in the inner peripheral adjacent region A22. For example, this arrangement of the invisible light emitting pixels 3 is also possible. For example, the display pixel 2 may include the light emitting layer 55 that emits at least visible light (e.g., white light, white light and infrared light, or red light, green light, and blue light) in visible light and invisible light, and the invisible light emitting pixel 3 may include the light emitting layer 55 that emits invisible light (e.g., infrared light). In this way, the display pixel 2 and the invisible light emitting pixel 3 can also be obtained.

As described with reference to FIGS. 10 to 36 and the like, the invisible light may include at least one of infrared light and ultraviolet light. For example, this pixel that emits invisible light can be used as the invisible light emitting pixel 3.

As described with reference to FIGS. 20 to 36 and the like, the visible light cut filter (e.g., the filter 7IR and the visible light cut filter 13) may be arranged in the adjacent region A2. This makes it possible to suppress leakage of visible light from the adjacent region A2.

As described with reference to FIGS. 2, 3, 5, 6, and the like, the outer peripheral adjacent region A21 may be the corner region of the display region A1. For example, when the corner region of the display region A1 is an area in which the image is not displayed in order to correct the distortion aberration of the magnifying lens, the influence on the resolution and the like of the display image can be reduced by arranging the invisible light emitting pixels 3 in this area.

The electronic apparatus 105 described with reference to FIGS. 37, 38, and the like is also one of the disclosed techniques. The electronic apparatus 105 includes the display device 110, the imaging device 120 that images invisible light, and the optical element 130 that guides the invisible light from the adjacent region A2 of the display device 110 to the user U and guides the invisible light reflected by the user U to the imaging device 120. For example, as illustrated in FIG. 37, the imaging device 120 may be arranged in the vicinity of the display device 110. As illustrated in FIG. 38, the imaging device 120 may be arranged at the position away from the display device 110. When the electronic apparatus 105 includes the display device 110 described above, it is possible to suppress an increase in size of the electronic apparatus 105 and to suppress deterioration in display performance.

### 4. OTHER MODIFIED EXAMPLES

### First Modified Example

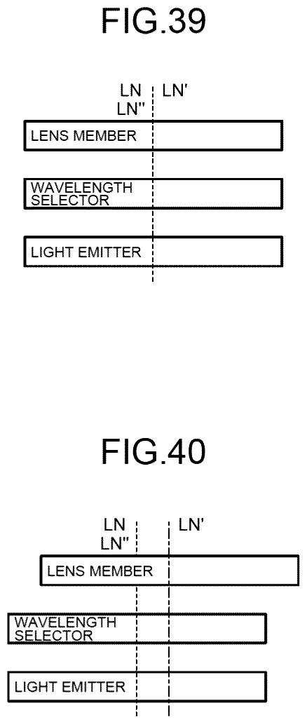

Other modified examples will be described. First, with reference to FIGS. 39 to 45, a modified example of a relationship between a normal line LN passing through a center of the sub-pixel R, the sub-pixel G, the sub-pixel B, the sub-pixel IR, and the like (hereinafter also referred to as “sub-pixel”), a normal line LN′ passing through a center of the lens 11 (hereinafter also referred to as a “lens member”), and a normal line LN″ passing through a center of the filter 7R, the filter 7G, the filter 7B, the filter 7IR, and the like (hereinafter also referred to as a “wavelength selector”) will be described. FIGS. 39 to 45 are conceptual diagrams illustrating a relationship among the normal line LN passing through the center of the sub-pixels, a normal line LN′ passing through the center of the lens member, and the normal line LN″ passing through the center of the wavelength selector. Note that, in the following description, the center of the sub-pixel is referred to as a center of a light emitter.

The size of the wavelength selector may be appropriately changed according to light emitted from the sub-pixel. A light absorption layer (black matrix layer) may be provided between the light absorption layer and the wavelength selector of the adjacent sub-pixels. In this case, the size of the light absorption layer may be appropriately changed according to the light emitted from the sub-pixel. Furthermore, the size of the wavelength selector may be appropriately changed according to a distance (offset amount) do between the normal line passing through the center of the sub-pixel and the normal line passing through the center of the wavelength selector. A planar shape of the wavelength selector may be the same as, similar to, or different from the planar shape of the lens member.

For example, as illustrated in FIG. 39, the normal line LN passing through the center of the light emitter, the normal line LN″ passing through the center of the wavelength selector, and the normal line LN′ passing through the center of the lens member may coincide with each other. In other words, the distance (offset amount) D₀ between the normal line passing through the center of the light emitter and the normal line passing through the center of the lens member and the distance (offset amount) do between the normal line passing through the center of the light emitter and the normal line passing through the center of the wavelength selector may be equal, which is 0 (zero).

As illustrated in FIG. 40, the normal line LN passing through the center of the light emitter and the normal line LN″ passing through the center of the wavelength selector coincide with each other, but the normal line LN passing through the center of the light emitter and the normal line LN″ passing through the center of the wavelength selector may not coincide with the normal line LN′ passing through the center of the lens member. In other words, D₀≠d₀=0 is acceptable.

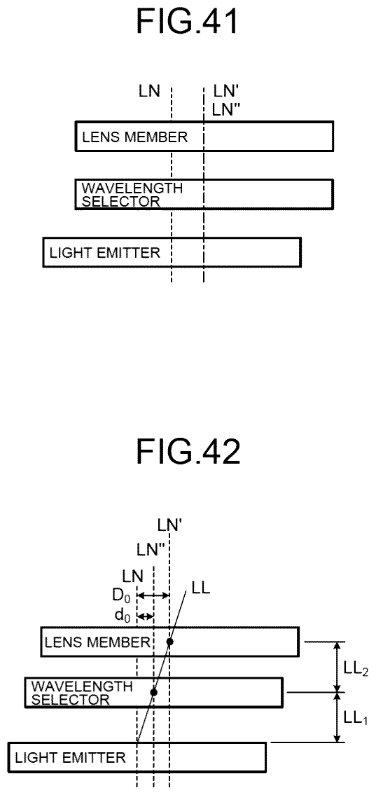

As illustrated in FIG. 41, the normal line LN passing through the center of the light emitter may not coincide with the normal line LN″ passing through the center of the wavelength selector and the normal line LN′ passing through the center of the lens member, and the normal line LN″ passing through the center of the wavelength selector may coincide with the normal line LN′ passing through the center of the lens member. In other words, D₀=d₀>0 is acceptable.

As illustrated in FIG. 42, the normal line LN passing through the center of the light emitter may not coincide with the normal line LN″ passing through the center of the wavelength selector and the normal line LN′ passing through the center of the lens member, and the normal line LN′ passing through the center of the lens member may not coincide with the normal line LN passing through the center of the light emitter and the normal line LN″ passing through the center of the wavelength selector. Here, the center of the wavelength selector (illustrated with black dot) is preferably located on a straight line LL connecting the center of the light emitter and the center of the lens member (illustrated with black dot).

Specifically, when a distance from the center of the light emitter in a thickness direction to the center of the wavelength selector is LL₁, and a distance from the center of the wavelength selector in the thickness direction to the center of the lens member is LL₂, the relationship is D₀>d₀>0, and it is preferable that d₀: D₀=LL₁:(LL₁+LL₂) is satisfied in consideration of manufacturing variations.

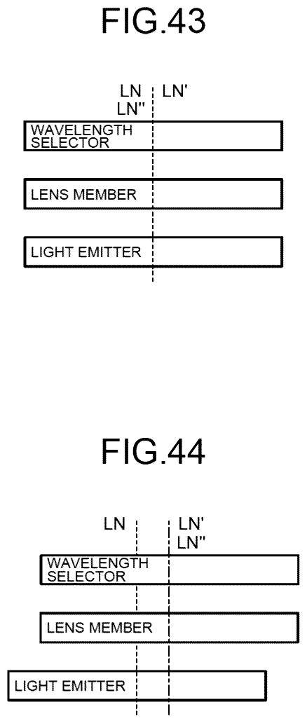

A laminating relationship between a wavelength distal end portion and the lens member may be switched. In this case, for example, as illustrated in FIG. 43, the normal line LN passing through the center of the light emitter, the normal line LN″ passing through the center of the wavelength selector, and the normal line LN′ passing through the center of the lens member may coincide with each other. In other words, D₀=d₀=0 is acceptable.

As illustrated in FIG. 44, the normal line LN passing through the center of the light emitter may not coincide with the normal line LN″ passing through the center of the wavelength selector and the normal line LN′ passing through the center of the lens member, and the normal line LN″ passing through the center of the wavelength selector may coincide with the normal line LN′ passing through the center of the lens member. In other words, D₀=d₀>0 is acceptable.

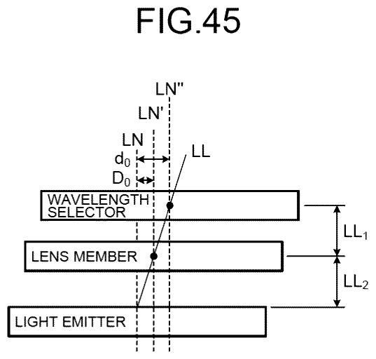

As illustrated in FIG. 45, the normal line LN passing through the center of the light emitter may not coincide with the normal line LN″ passing through the center of the wavelength selector and the normal line LN′ passing through the center of the lens member, and the normal line LN′ passing through the center of the lens member may not coincide with the normal line LN passing through the center of the light emitter and the normal line LN″ passing through the center of the wavelength selector. Here, the center of the wavelength selector is preferably located on the straight line LL connecting the center of the light emitter and the center of the lens member. Specifically, when a distance from the center of the light emitter in the thickness direction to the center of the wavelength selector (illustrated by black dot) is LL₁, and a distance from the center of the wavelength selector in the thickness direction to the center of the lens member (illustrated by black dot) is LL₂, the relationship is d₀>D₀>0, and it is preferable that D₀: d₀=LL₂:(LL₁+LL₂) is satisfied in consideration of manufacturing variations.

### Second Modified Example

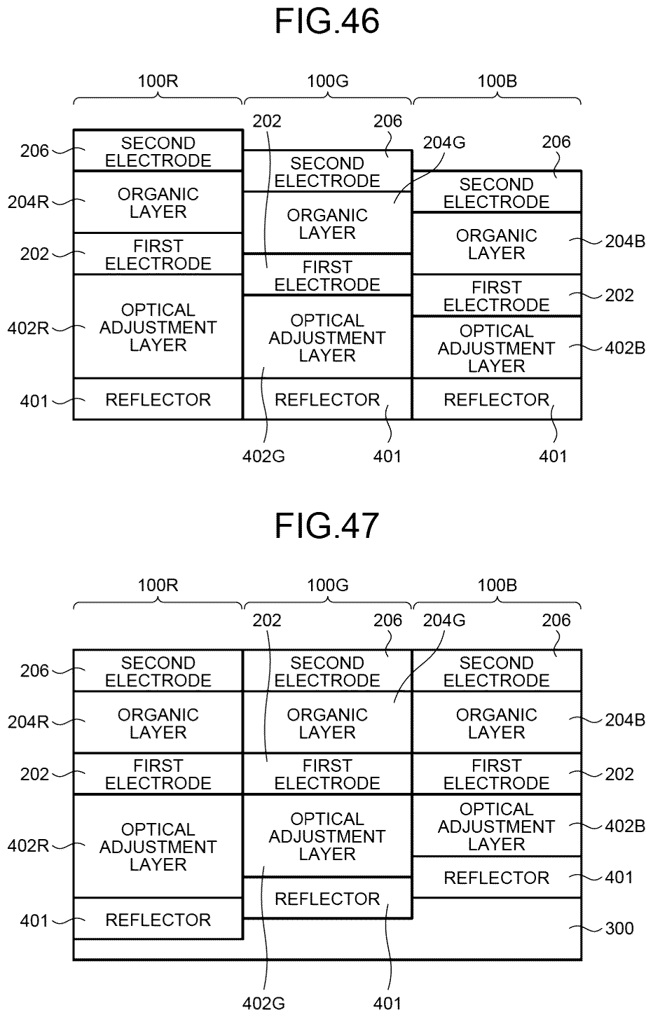

The sub-pixel may have a resonator structure that causes light generated in the light emitting layer 55 to resonate. This will be described with reference to FIGS. 46 to 52. FIGS. 46 to 52 are schematic cross-sectional views illustrating Examples 1 to 7 of the resonance structure.

Hereinafter, the sub-pixel R, the sub-pixel B, and the sub-pixel B described above will be described as an example of the sub-pixel. In FIGS. 46 to 52, these sub-pixels are referred to as a sub-pixel 100R, a sub-pixel 100G, and a sub-pixel 100B, respectively. The light emitting layer 55 is an organic material layer of the OLED, and is referred to as an organic layer 204R, an organic layer 204G, and an organic layer 204B in the drawings. The above-described first electrode 51 is referred to as a first electrode 202 in the drawings. The above-described second electrode 52 is referred to as a second electrode 206 in the drawings. The above-described substrate 1 is referred to as a substrate 300 in the drawings.

### Resonator Structure: Example 1

FIG. 46 is a schematic cross-sectional view illustrating Example 1 of the resonator structure. In Example 1, the first electrode (e.g., anode electrode) 202 is formed with a common film thickness in each sub-pixel. The same applies to the second electrode (e.g., cathode electrode) 206.

As illustrated in FIG. 46, a reflector 401 is arranged below the first electrode 202 of the sub-pixel 100 with an optical adjustment layer 402 interposed therebetween. The resonator structure that resonates light generated by the organic layer (specifically, light emitting layer) 204 is formed between the reflector 401 and the second electrode 206.

The reflector 401 is formed with a common film thickness in each sub-pixel 100. The film thickness of the optical adjustment layer 402 varies depending on the color to be displayed by the sub-pixel 100. Since the optical adjustment layers 402R, 402G, and 402B have different film thicknesses, it is possible to set an optical distance at which optimum resonance occurs for a wavelength of light corresponding to a color to be displayed.

In the example illustrated in FIG. 46, upper surfaces of the reflectors 401 in the sub-pixels 100R, 100G, and 100B are arranged so as to be aligned. As described above, since the film thickness of the optical adjustment layers 402 varies depending on the color to be displayed by the sub-pixel 100, the position of the upper surface of the second electrode 206 varies depending on types of the sub-pixels 100R, 100G, and 100B.

The reflector 401 can be formed using, for example, a metal such as aluminum (Al), silver (Ag), or copper (Cu), or an alloy containing these metals as a main component.

The optical adjustment layer 402 can be made of an inorganic insulating material such as silicon nitride (SiNx), silicon oxide (SiOx), or silicon oxynitride (SiOxNy), or an organic resin material such as an acrylic resin or a polyimide resin. The optical adjustment layer 402 may be a single layer or a laminated film of a plurality of materials. Furthermore, the number of laminated layers may be different according to the type of the sub-pixel 100.

The first electrode 202 can be formed using, for example, a transparent conductive material such as indium tin oxide (ITO), indium zinc oxide (IZO), or zinc oxide (ZnO).

The second electrode 206 preferably functions as a semi-transmission reflection film. The second electrode 206 can be formed using magnesium (Mg), silver (Ag), a magnesium-silver alloy (MgAg) containing these as a main component, an alloy containing an alkali metal or an alkaline earth metal, or the like.

### Resonator Structure: Example 2

FIG. 47 is a schematic cross-sectional view illustrating Example 2 of the resonator structure. Also in Example 2, the first electrode 202 and the second electrode 206 are formed with a common film thickness in each sub-pixel 100.

Also in Example 2, the reflector 401 is arranged below the first electrode 202 of the sub-pixel 100 with the optical adjustment layer 402 interposed therebetween. The resonator structure that resonates light generated by the organic layer 204 is formed between the reflector 401 and the second electrode 206. As in Example 1, the reflector 401 is formed with the common film thickness in each sub-pixel 100, and the film thickness of the optical adjustment layer 402 varies depending on the color to be displayed by the sub-pixel 100.

In Example 1 illustrated in FIG. 46, the upper surfaces of the reflectors 401 in the sub-pixels 100R, 100G, and 100B are arranged so as to be aligned, and the positions of the upper surfaces of the second electrodes 206 are different according to the types of the sub-pixels 100R, 100G, and 100B.

On the other hand, in Example 2 illustrated in FIG. 47, the upper surfaces of the second electrodes 206 are arranged so as to be aligned in the sub-pixels 100R, 100G, and 100B. In order to align the upper surfaces of the second electrodes 206, the upper surfaces of the reflectors 401 in the sub-pixels 100R, 100G, and 100B are arranged differently according to the type of the sub-pixels 100R, 100G, and 100B. Therefore, the lower surface of the reflector 401 has a stair shape according to the type of the sub-pixels 100R, 100G, and 100B.

Materials and the like configuring the reflector 401, the optical adjustment layer 402, the first electrode 202, and the second electrode 206 are similar to the those described in Example 1, and thus the description thereof is omitted.

### Resonator Structure: Example 3

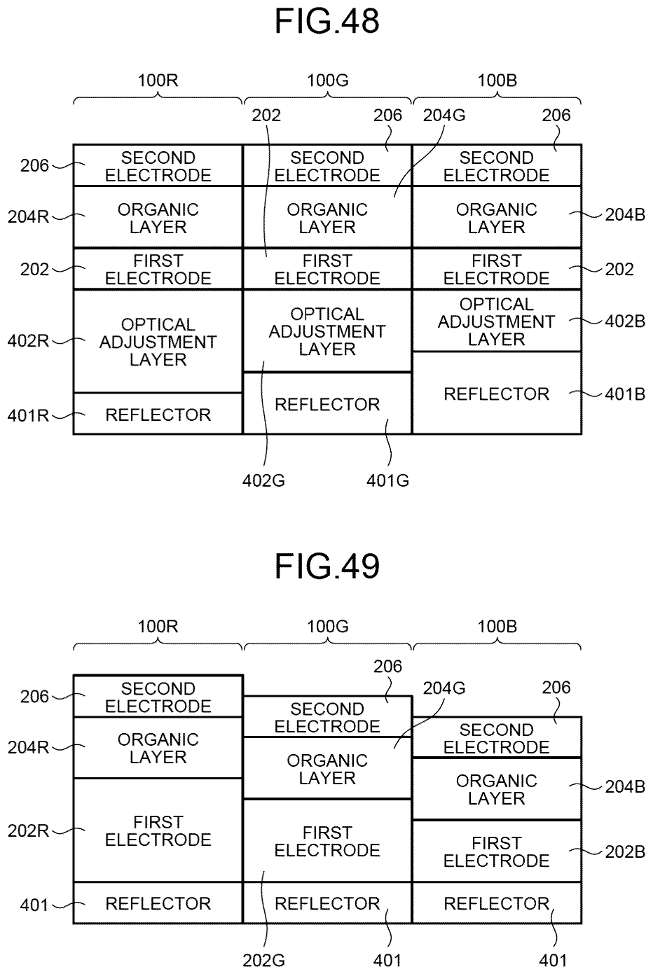

FIG. 48 is a schematic cross-sectional view for explaining Example 3 of the resonator structure. Also in Example 3, the first electrode 202 and the second electrode 206 are formed with the common film thickness in each sub-pixel 100.

Also in Example 3, the reflector 401 is arranged below the first electrode 202 of the sub-pixel 100 with the optical adjustment layer 402 interposed therebetween. The resonator structure that resonates light generated by the organic layer 204 is formed between the reflector 401 and the second electrode 206. As in Example 1 and Example 2, the film thickness of the optical adjustment layer 402 varies depending on the color to be displayed by the sub-pixel 100. Then, similarly to Example 2, the positions of the upper surfaces of the second electrodes 206 are arranged so as to be aligned in the sub-pixels 100R, 100G, and 100B.

In Example 2 illustrated in FIG. 47, in order to align the upper surfaces of the second electrodes 206, the lower surface of the reflector 401 has a stepped shape according to the type of the sub-pixels 100R, 100G, and 100B.

On the other hand, in Example 3 illustrated in FIG. 48, the film thickness of the reflector 401 is set to be different according to the type of the sub-pixels 100R, 100G, and 100B. More specifically, the film thickness is set such that the lower surfaces of the reflectors 401R, 401G, and 401B are aligned.

Materials and the like configuring the reflector 401, the optical adjustment layer 402, the first electrode 202, and the second electrode 206 are similar to the those described in Example 1, and thus the description thereof is omitted.

### Resonator Structure: Example 4

FIG. 49 is a schematic cross-sectional view illustrating Example 4 of the resonator structure.

In Example 1 illustrated in FIG. 46, the first electrode 202 and the second electrode 206 of the sub-pixel 100 are formed with the common film thickness. Then, the reflector 401 is arranged below the first electrode 202 of the sub-pixel 100 with the optical adjustment layer 402 interposed therebetween.

On the other hand, in Example 4 illustrated in FIG. 49, the optical adjustment layer 402 is omitted, and the film thickness of the first electrode 202 is set to be different according to the type of the sub-pixels 100R, 100G, and 100B.

The reflector 401 is formed with a common film thickness in each sub-pixel 100. The film thickness of the first electrode 202 varies depending on the color to be displayed by the sub-pixel 100. Since the first electrodes 202R, 202G, and 202B have different film thicknesses, it is possible to set an optical distance that generates optimum resonance for the wavelength of light according to the color to be displayed.

Materials and the like configuring the reflector 401, the first electrode 202, and the second electrode 206 are similar to those described in Example 1, and thus description thereof is omitted.

### Resonator Structure: Example 5

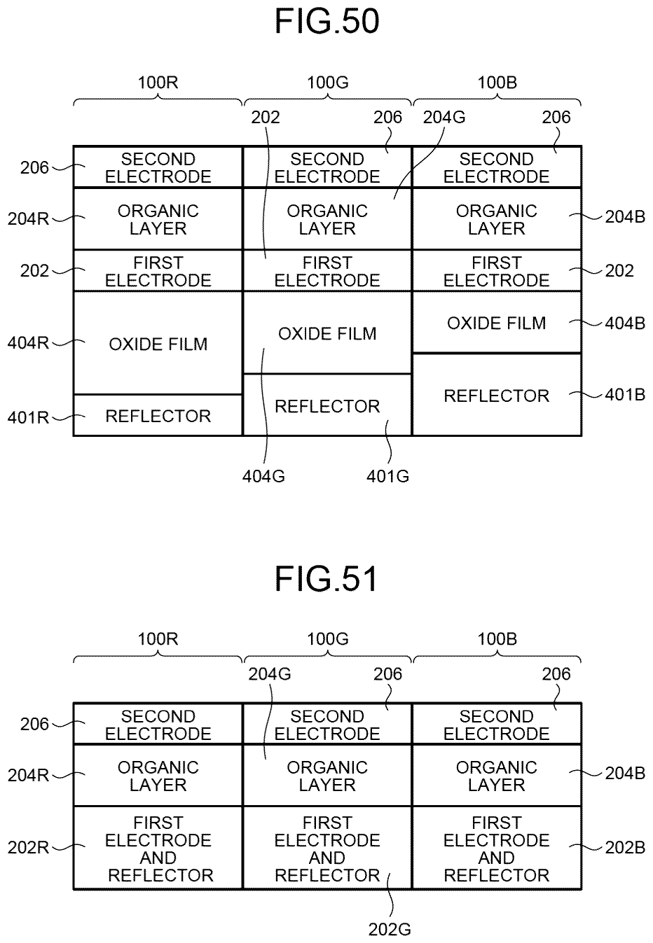

FIG. 50 is a schematic cross-sectional view for explaining Example 5 of the resonator structure.

In Example 1 illustrated in FIG. 46, the first electrode 202 and the second electrode 206 are formed with the common film thickness in each sub-pixel 100. Then, the reflector 401 is arranged below the first electrode 202 of the sub-pixel 100 with the optical adjustment layer 402 interposed therebetween.

On the other hand, in Example 5 illustrated in FIG. 50, the optical adjustment layer 402 is omitted, and instead, an oxide film 404 is formed on the surface of the reflector 401. The film thickness of the oxide film 404 is set to be different according to the type of the sub-pixels 100R, 100G, and 100B.

The film thickness of the oxide film 404 varies depending on the color to be displayed by the sub-pixel 100. Since oxide films 404R, 404G, and 404B have different film thicknesses, it is possible to set an optical distance at which optimum resonance occurs for a wavelength of light corresponding to a color to be displayed.

The oxide film 404 is a film obtained by oxidizing the surface of the reflector 401, and is made of, for example, aluminum oxide, tantalum oxide, titanium oxide, magnesium oxide, or zirconium oxide. The oxide film 404 functions as an insulating film for adjusting an optical path length (optical distance) between the reflector 401 and the second electrode 206.

The oxide film 404 having different film thicknesses depending on the type of the sub-pixels 100R, 100G, and 100B can be formed, for example, as follows.

First, an electrolytic solution is filled in a container, and a substrate on which the reflector 401 is formed is immersed in the electrolytic solution. Further, the electrode is arranged so as to face the reflector 401.

Then, a positive voltage is applied to the reflector 401 with reference to the electrode, and the reflector 401 is anodized. The film thickness of the oxide film by the anodic oxidation is proportional to a voltage value with respect to the electrode. Therefore, anodization is performed in a state where voltages corresponding to the types of the sub-pixels 100R, 100G, and 100B are applied to the reflectors 401R, 401G, and 401B, respectively. As a result, the oxide films 404 having different film thicknesses can be collectively formed.

Materials and the like configuring the reflector 401, the first electrode 202, and the second electrode 206 are similar to those described in Example 1, and thus description thereof is omitted.

### Resonator Structure: Example 6

FIG. 51 is a schematic cross-sectional view illustrating Example 6 of the resonator structure. In Example 6, the sub-pixel 100 is configured by laminating the first electrode 202, the organic layer 204, and the second electrode 206. However, in Example 6, the first electrode 202 is formed to function as both an electrode and a reflector. The first electrode (also reflector) 202 is made of a material having an optical constant selected according to the type of the sub-pixels 100R, 100G, and 100B. Since a phase shift by the first electrode (also serving as the reflector) 202 is different, it is possible to set an optical distance that generates optimum resonance for the wavelength of light according to the color to be displayed.

The first electrode (also serving as a reflector) 202 can be made of a single metal such as aluminum (Al), silver (Ag), gold (Au), or copper (Cu), or an alloy containing these metals as a main component. For example, the first electrode (also serving as a reflector) 202R of the sub-pixel 100R may be made of copper (Cu), and the first electrode (also serving as a reflector) 202G of the sub-pixel 100G and the first electrode (also serving as a reflector) 202B of the sub-pixel 100B may be made of aluminum.

The material and the like configuring the second electrode 206 are similar to those described in Example 1, and thus the description thereof will be omitted.

### Resonator Structure: Example 7

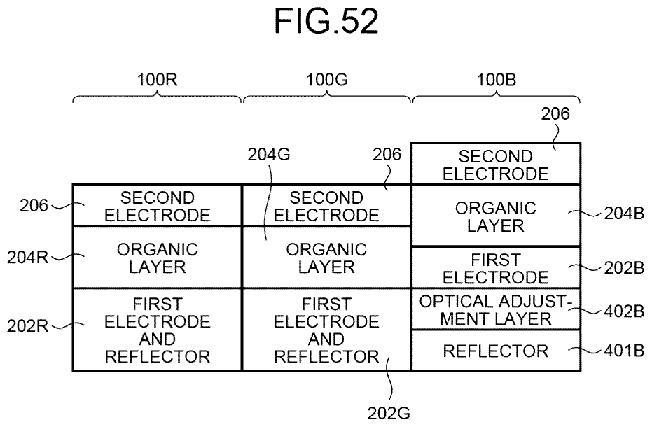

FIG. 52 is a schematic cross-sectional view illustrating Example 7 of the resonator structure. In Example 7, basically, Example 6 is applied to the sub-pixels 100R and 100G, and Example 1 is applied to the sub-pixel 100B. Also in this configuration, it is possible to set an optical distance that causes optimum resonance for the wavelength of light according to the color to be displayed.

The first electrodes (also serving as reflectors) 202R and 202G used for the sub-pixels 100R and 100G can be made of a single metal such as aluminum (Al), silver (Ag), gold (Au), or copper (Cu), or an alloy containing these metals as a main component.

Materials and the like configuring the reflector 401B, the optical adjustment layer 402B, and the first electrode 202B used for the sub-pixel 100B are similar to those described in Example 1, and thus description thereof is omitted.

### 5. APPLICATION EXAMPLES

For example, the technology according to the present disclosure may be applied to a display unit or the like of various electronic apparatuses. Therefore, examples of an electronic apparatus to which the present technology can be applied will be described below.

### First Application Example

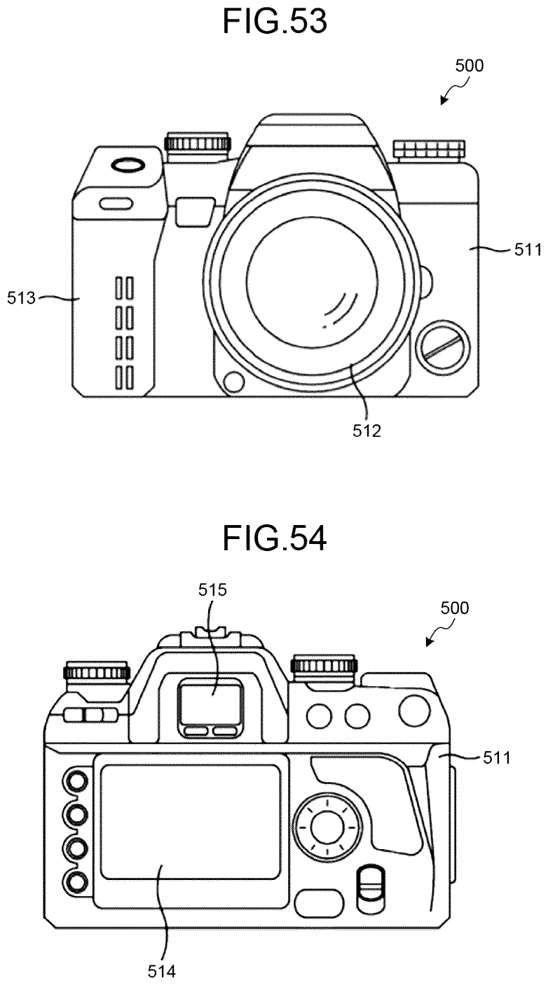

FIG. 53 is a front view illustrating an example of an appearance of a digital still camera 500. FIG. 54 is a rear view illustrating an example of the appearance of the digital still camera 500. The digital still camera 500 is a lens interchangeable single lens reflex type, and includes an interchangeable imaging lens unit (interchangeable lens) 512 substantially at a front center of a camera body part (camera body) 511, and a grip part 513 to be held by a photographer on a front left side.

A monitor 514 is provided at a position shifted to the left from a rear center of the camera body 511. An electronic viewfinder (eyepiece window) 515 is provided above the monitor 514. By looking into the electronic viewfinder 515, the photographer can determine layout by visually recognizing an optical image of a subject guided by the imaging lens unit 512. As the monitor 514 and the electronic viewfinder 515, the display device 110 described above can be used.

### Second Application Example

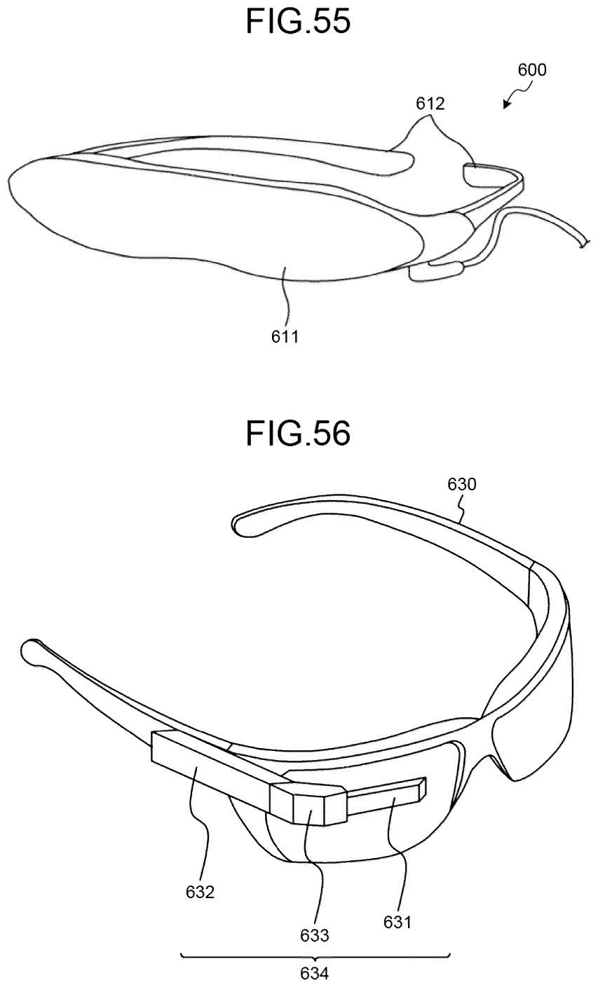

FIG. 55 is an external view of a head mounted display 600. The head mounted display 600 includes, for example, ear hooking portions 612 to be worn on a user head on both sides of a glass-shaped display unit 611. In the head mounted display 600, the display device 110 described above can be used as the display unit 611.

### Third Application Example

FIG. 56 is an external view of a see-through head mounted display 634. The see-through head mounted display 634 includes a main body 632, an arm 633, and a lens barrel 631.

The main body 632 is connected to an arm 643 and glasses 630. Specifically, an end portion of the main body 632 in a long side direction is coupled to the arm 633, and one side of a side surface of the main body 632 is coupled to the glasses 630 via a connecting member. Note that the main body 632 may be directly mounted on a head of a human body.

The main body 632 incorporates a control board for controlling the operation of the see-through head mounted display 634 and a display unit. The arm 633 connects the main body 632 and the lens barrel 631 and supports the lens barrel 631. Specifically, the arm 633 is coupled to an end of the main body 632 and an end of the lens barrel 631 to fix the lens barrel 631. Furthermore, the arm 633 incorporates a signal line for communicating data related to an image provided from the main body 632 to the lens barrel 631.

The lens barrel 631 projects image light provided from the main body 632 via the arm 633 toward eyes of a user wearing the see-through head mounted display 634 through the eyepiece. In the see-through head mounted display 634, the display device 110 described above can be used as the display unit of the main body 632.

### Fourth Application Example

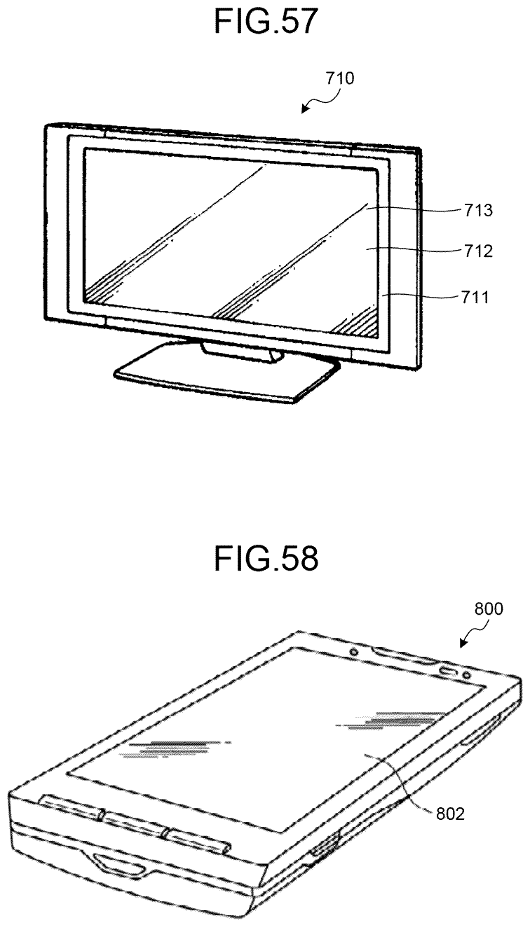

FIG. 57 illustrates an example of an appearance of a television apparatus 710. The television apparatus 710 includes, for example, a video display screen unit 711 including a front panel 712 and a filter glass 713, and the video display screen unit 711 is configured with the display device 110 described above.

### Fifth Application Example

FIG. 58 illustrates an example of an appearance of a smartphone 800. The smartphone 800 includes a display unit 802 that displays various types of information, an operation unit including a button that receives an operation input by the user, and the like. The display unit 802 can be the display device 110 described above.

### Sixth Application Example

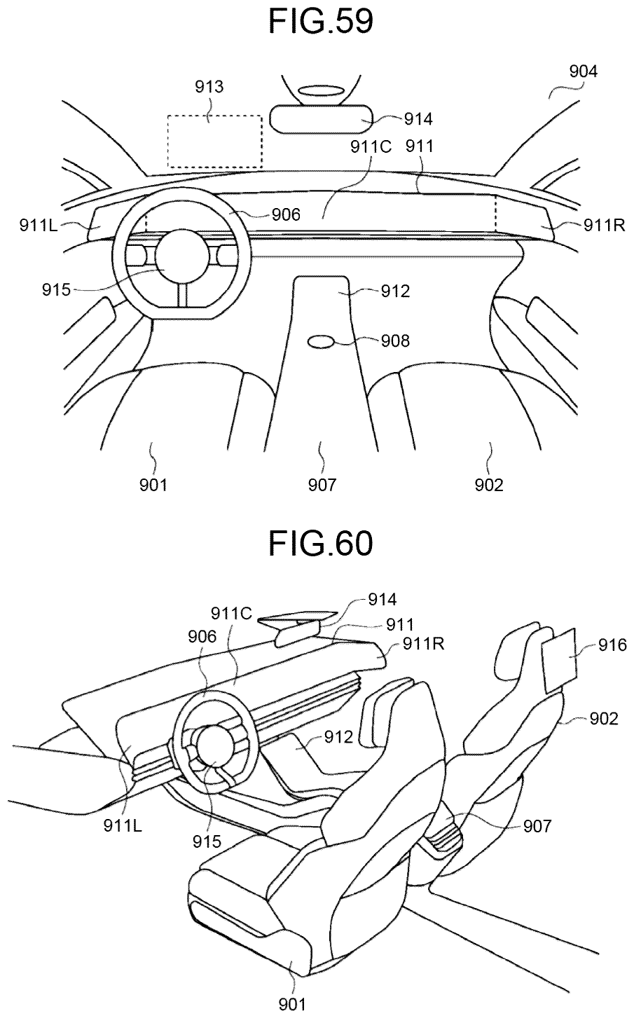

FIGS. 59 and 60 are views illustrating an internal configuration of an automobile including the display device 110 according to the embodiment of the present disclosure. Specifically, FIG. 59 is a view illustrating a state of the inside of the automobile from the rear to the front of the automobile, and FIG. 60 is a view illustrating a state of the inside of the automobile from the oblique rear to the oblique front of the automobile.

The automobile illustrated in FIGS. 59 and 60 includes a center display 911, a console display 912, a head-up display 913, a digital rear mirror 914, a steering wheel display 915, and a rear entertainment display 916. The display device 110 described above can be applied to some or all of these displays.

The center display 911 is arranged on a center console 907 at a position facing a driver's seat 901 and a front passenger seat 902. FIGS. 59 and 60 illustrate an example of the center display 911 having a horizontally long shape extending from the driver's seat 901 to the front passenger seat 902, but a screen size and an arrangement location of the center display 911 are arbitrary. The center display 911 can display information detected by various sensors (not illustrated). As a specific example, the center display 911 can display a captured image captured by an image sensor, a distance image to an obstacle in front of or on a side of the automobile measured by a time of flight (ToF) sensor, a passenger's body temperature detected by an infrared sensor, and the like. The center display 911 can be used to display, for example, at least one of safety information, operation information, a life log, health information, authentication/identification information, and entertainment information.

The safety information is information such as doze detection, inattentive behavior detection, detection of mischief by a child in the vehicle, presence or absence of wearing of a seat belt, and detection of leaving of passenger, and is information detected by, for example, a sensor (not illustrated) overlaid on the back side of the center display 1911. The operation information is detected by the sensor based on a gesture related to the operation of the passenger. The gesture detected may include operation of various equipment in the automobile. For example, operations of air conditioner, a navigator, an audio/visual (AV) device, and a lighting device are detected. The life log includes a life log of all passengers. For example, the life log includes a behavior record of each passenger in the vehicle. By acquiring and storing the life log, it is possible to confirm the state of the passenger at the time of an accident. In the health information, the body temperature of the passenger is detected by a temperature sensor, and a health state of the passenger is estimated based on the detected body temperature. Alternatively, a face of the passenger may be imaged using an image sensor, and the health state of the passenger may be estimated from the imaged facial expression. Furthermore, a conversation with the passenger using automatic voice may be performed to estimate the health condition of the passenger based on an answer from the passenger. The authentication/identification information includes a keyless entry function for performing face authentication using a sensor and an automatic adjustment function of a seat height and a position by face identification. The entertainment information includes a function of detecting, by the sensor, operation information of an AV device by the passenger and a function of recognizing the face of the passenger by the sensor and providing content suitable for the passenger by the AV device.

For example, the console display 912 can be used to display the life log information. The console display 912 is arranged near a shift lever 908 of the center console 907 between the driver's seat 901 and the front passenger seat 902. The console display 912 can also display information detected by various sensors (not illustrated). In addition, the console display 912 may display an image around the vehicle captured by the image sensor, or may display a distance image to an obstacle around the vehicle.

Head-up display 913 is virtually displayed on windshield 904 in front of the driver's seat 901. The head-up display 913 can be used to display, for example, at least one of the safety information, the operation information, the life log, the health information, the authentication/identification information, and the entertainment information. Since the head-up display 913 is virtually arranged in front of the driver's seat 901 in many cases, the head-up display is suitable for displaying information directly related to the operation of the automobile such as a speed of the automobile and the remaining fuel (battery).

The digital rear mirror 914 can display not only the back side of the automobile but also the state of the passenger in a rear seat, and thus can be used to display the life log information, for example, by overlaying a sensor (not illustrated) on a back surface side of the digital rear mirror 914.

The steering wheel display 915 is arranged near the center of the steering wheel 906 of the automobile. The steering wheel display 915 can be used to display, for example, at least one of the safety information, the operation information, the life log, the health information, the authentication/identification information, and the entertainment information. In particular, since the steering wheel display 915 is close to a driver's hand, it is suitable for displaying the life log information such as the body temperature of the driver, or for displaying information related to the operation of the AV device, the air conditioner, or the like.

The rear entertainment display 916 is attached to the back side of the driver's seat 901 and the front passenger seat 902, and is for viewing by a passenger in the rear seat. The rear entertainment display 916 can be used to display, for example, at least one of the safety information, the operation information, the life log, the health information, the authentication/identification information, and the entertainment information. In particular, since the rear entertainment display 916 is in front of the passenger in the rear seat, information related to the passenger in the rear seat is displayed. For example, information regarding the operation of the AV device or the air conditioner may be displayed, or a result of measuring the body temperature or the like of the passenger in the rear seat by a temperature sensor (not illustrated) may be displayed.

Note that the effects described in the present disclosure are merely examples and are not limited to the subject matter disclosed. There may be other effects.

The technical scope of the present disclosure is not limited to the above-described embodiment, and various modifications can be made without departing from the gist of the present disclosure. In addition, the components of different embodiments and modifications may be appropriately combined.

The present technology may also have the following configurations.
(1) A display device comprising:
   a display region in which a display pixel that emits visible light is arranged; and
   an adjacent region in which an invisible light emitting pixel that emits at least invisible light in visible light and invisible light is arranged, the adjacent region being adjacent to the display region along an edge of the display region.
(2) The display device according to claim 1), wherein
   the adjacent region includes at least one of an outer peripheral adjacent region that is at least a part of an outer peripheral region of the display region and an inner peripheral adjacent region that is at least a part of an inner peripheral region of the display region.
(3) The display device according to (2), wherein
   the invisible light emitting pixel with a function of the display pixel is arranged in the inner peripheral adjacent region.
(4) The display device according to (2), wherein
   the display pixel and the invisible light emitting pixel commonly include a light emitting layer that emits visible light and invisible light, the display pixel includes a filter that allows the visible light to pass in the visible light and the invisible light from the light emitting layer, and the invisible light emitting pixel includes a filter that allows the invisible light to pass in the visible light and the invisible light from the light emitting layer.
(5) The display device according to (2), wherein
   the display pixel and the invisible light emitting pixel commonly include a light emitting layer that emits visible light,
   the display pixel includes a filter that allows the visible light from the light emitting layer to pass, and
   the invisible light emitting pixel includes a wavelength conversion layer that converts the visible light from the light emitting layer into invisible light.
(6) The display device according to (2), wherein
   the display pixel includes a plurality of sub-pixels corresponding to different colors,
   the plurality of sub-pixels and the invisible light emitting pixel include a light emitting layer that emits visible light,
   a part of the plurality of sub-pixels includes a wavelength conversion layer that converts the visible light from the light emitting layer into light of a color corresponding to the part of the plurality of sub-pixels, and
   the invisible light emitting pixel includes a wavelength conversion layer that converts the visible light from the light emitting layer into invisible light.
(7) The display device according to (2), wherein
   the display pixel includes a plurality of sub-pixels corresponding to different colors,
   the plurality of sub-pixels includes a light emitting layer that emits visible light,
   the invisible light emitting pixel includes a light emitting layer that emits invisible light, and
   a part of the plurality of sub-pixels includes a wavelength conversion layer that converts the visible light from the light emitting layer into a color corresponding to the part of the plurality of sub-pixels.
(8) The display device according to (2), wherein
   the display pixel includes a plurality of sub-pixels corresponding to different colors,
   the plurality of sub-pixels includes a light emitting layer that emits visible light and a filter that allows light of a corresponding color to pass, and
   the invisible light emitting pixel includes a light emitting layer that emits invisible light.
(9) The display device according to (2), wherein
   the display pixel and the invisible light emitting pixel include a light emitting layer that emits visible light, and
   the invisible light emitting pixel includes a wavelength conversion layer that converts the visible light from the light emitting layer into invisible light.
(10) The display device according to (2), wherein
   the display pixel and the invisible light emitting pixel include a light emitting layer that emits invisible light, and
   the display pixel includes a wavelength conversion layer that converts the invisible light from the light emitting layer into visible light.
(11) The display device according to (1), wherein
   the adjacent region includes an outer peripheral adjacent region that is a part of an outer peripheral region of the display region,
   the outer peripheral region of the display region includes a common electrode region or a circuit region of a visible light emitting element and a common electrode region or a circuit region of an invisible light emitting element, and
   the outer peripheral adjacent region in which the invisible light emitting pixel is arranged is the common electrode region or the circuit region of the visible light emitting element.
(12) The display device according to (1), wherein
   the adjacent region includes an inner peripheral adjacent region that is a part of an inner peripheral region of the display region,
   the invisible light emitting pixel with a function of the display pixel is arranged in the inner peripheral adjacent region, and
   the display region has an outer peripheral region that includes a common electrode region or a circuit region of an invisible light emitting element.
(13) The display device according to (1), wherein
   the adjacent region includes an outer peripheral adjacent region that is a part of an outer peripheral region of the display region and an inner peripheral adjacent region that is a part of an inner peripheral region of the display region,
   the outer peripheral region of the display region includes a common electrode region or a circuit region of a visible light emitting element and a common electrode region or a circuit region of an invisible light emitting element,
   the outer peripheral adjacent region in which the invisible light emitting pixel is arranged is the common electrode region or the circuit region of the visible light emitting element, and
   the invisible light emitting pixel with a function of the display pixel is arranged in the inner peripheral adjacent region.
(14) The display device according to (13), wherein
   the display pixel includes a light emitting layer that emits at least visible light in visible light and invisible light, and
   the invisible light emitting pixel includes a light emitting layer that emits invisible light.
(15) The display device according to any one of (1) to (14), wherein
   the invisible light includes at least infrared light or ultraviolet light.
(16) The display device according to any one of (1) to (15), wherein
   a visible light cut filter is arranged in the adjacent region.
(17) The display device according to (2), wherein
   the inner peripheral adjacent region is a corner region of the display region.
(18) An electronic apparatus comprising:
   a display device including a display region in which a display pixel that emits visible light is arranged, and an adjacent region in which an invisible light emitting pixel that emits at least invisible light in visible light and invisible light is arranged, the adjacent region being adjacent to the display region along an edge of the display region;
   an imaging device that captures an image of invisible light; and
   an optical element that guides the invisible light from the adjacent region of the display device to a user and guides invisible light reflected by the user to the imaging device.
(19) The electronic apparatus according to (18), wherein
   the imaging device is arranged near the display device.
(20) The electronic apparatus according to (18), wherein
   the imaging device is arranged at a position away from the display device.

### REFERENCE SIGNS LIST

1 SUBSTRATE
2 DISPLAY PIXEL
3 INVISIBLE LIGHT EMITTING PIXEL
4 INSULATING LAYER
5 LIGHT EMITTING ELEMENT LAYER
51 FIRST ELECTRODE
51a ELECTRODE
51b ELECTRODE
52 SECOND ELECTRODE
53 THIRD ELECTRODE
54 INFRARED LIGHT ELECTRODE
55 LIGHT EMITTING LAYER
56 ANODE
57 CATHODE
58 LED
6 PROTECTIVE LAYER
7 FILTER LAYER
7B FILTER
7BIR FILTER
7G FILTER
7GIR FILTER
7IR FILTER
7R FILTER
7RIR FILTER
8 RESIN LAYER
9 GLASS LAYER
11 LENS
12B WAVELENGTH CONVERSION LAYER
12G WAVELENGTH CONVERSION LAYER
12IR WAVELENGTH CONVERSION LAYER
12R WAVELENGTH CONVERSION LAYER
13 VISIBLE LIGHT CUT FILTER
105 ELECTRONIC APPARATUS
110 DISPLAY DEVICE
120 IMAGING DEVICE
130 OPTICAL ELEMENT
130a LENS
130b HALF MIRROR
A1 DISPLAY REGION
A2 ADJACENT REGION
A21 OUTER PERIPHERAL ADJACENT REGION
A22 INNER PERIPHERAL ADJACENT REGION
A3 COMMON PERIPHERAL REGION
A4 COMMON PERIPHERAL REGION
B SUB-PIXEL
G SUB-PIXEL
IR SUB-PIXEL
R SUB-PIXEL
U USER

1. A display device comprising:
a display region in which a display pixel that emits visible light is arranged; and
an adjacent region in which an invisible light emitting pixel that emits at least invisible light in visible light and invisible light is arranged, the adjacent region being adjacent to the display region along an edge of the display region.

2. The display device according to claim 1, wherein
the adjacent region includes at least one of an outer peripheral adjacent region that is at least a part of an outer peripheral region of the display region and an inner peripheral adjacent region that is at least a part of an inner peripheral region of the display region.

3. The display device according to claim 2, wherein
the invisible light emitting pixel with a function of the display pixel is arranged in the inner peripheral adjacent region.

4. The display device according to claim 2, wherein
the display pixel and the invisible light emitting pixel commonly include a light emitting layer that emits visible light and invisible light,
the display pixel includes a filter that allows the visible light to pass in the visible light and the invisible light from the light emitting layer, and
the invisible light emitting pixel includes a filter that allows the invisible light to pass in the visible light and the invisible light from the light emitting layer.

5. The display device according to claim 2, wherein
the display pixel and the invisible light emitting pixel commonly include a light emitting layer that emits visible light,
the display pixel includes a filter that allows the visible light from the light emitting layer to pass, and
the invisible light emitting pixel includes a wavelength conversion layer that converts the visible light from the light emitting layer into invisible light.

6. The display device according to claim 2, wherein
the display pixel includes a plurality of sub-pixels corresponding to different colors,
the plurality of sub-pixels and the invisible light emitting pixel include a light emitting layer that emits visible light,
a part of the plurality of sub-pixels includes a wavelength conversion layer that converts the visible light from the light emitting layer into light of a color corresponding to the part of the plurality of sub-pixels, and
the invisible light emitting pixel includes a wavelength conversion layer that converts the visible light from the light emitting layer into invisible light.

7. The display device according to claim 2, wherein
the display pixel includes a plurality of sub-pixels corresponding to different colors,
the plurality of sub-pixels includes a light emitting layer that emits visible light,
the invisible light emitting pixel includes a light emitting layer that emits invisible light, and
a part of the plurality of sub-pixels includes a wavelength conversion layer that converts the visible light from the light emitting layer into a color corresponding to the part of the plurality of sub-pixels.

8. The display device according to claim 2, wherein
the display pixel includes a plurality of sub-pixels corresponding to different colors,
the plurality of sub-pixels includes a light emitting layer that emits visible light and a filter that allows light of a corresponding color to pass, and
the invisible light emitting pixel includes a light emitting layer that emits invisible light.

9. The display device according to claim 2, wherein
the display pixel and the invisible light emitting pixel include a light emitting layer that emits visible light, and
the invisible light emitting pixel includes a wavelength conversion layer that converts the visible light from the light emitting layer into invisible light.

10. The display device according to claim 2, wherein
the display pixel and the invisible light emitting pixel include a light emitting layer that emits invisible light, and
the display pixel includes a wavelength conversion layer that converts the invisible light from the light emitting layer into visible light.

11. The display device according to claim 1, wherein
the adjacent region includes an outer peripheral adjacent region that is a part of an outer peripheral region of the display region,
the outer peripheral region of the display region includes a common electrode region or a circuit region of a visible light emitting element and a common electrode region or a circuit region of an invisible light emitting element, and
the outer peripheral adjacent region in which the invisible light emitting pixel is arranged is the common electrode region or the circuit region of the visible light emitting element.

12. The display device according to claim 1, wherein
the adjacent region includes an inner peripheral adjacent region that is a part of an inner peripheral region of the display region,
the invisible light emitting pixel with a function of the display pixel is arranged in the inner peripheral adjacent region, and
the display region has an outer peripheral region that includes a common electrode region or a circuit region of an invisible light emitting element.

13. The display device according to claim 1, wherein
the adjacent region includes an outer peripheral adjacent region that is a part of an outer peripheral region of the display region and an inner peripheral adjacent region that is a part of an inner peripheral region of the display region,
the outer peripheral region of the display region includes a common electrode region or a circuit region of a visible light emitting element and a common electrode region or a circuit region of an invisible light emitting element,
the outer peripheral adjacent region in which the invisible light emitting pixel is arranged is the common electrode region or the circuit region of the visible light emitting element, and
the invisible light emitting pixel with a function of the display pixel is arranged in the inner peripheral adjacent region.

14. The display device according to claim 13, wherein
the display pixel includes a light emitting layer that emits at least visible light in visible light and invisible light, and
the invisible light emitting pixel includes a light emitting layer that emits invisible light.

15. The display device according to claim 1, wherein
the invisible light includes at least infrared light or ultraviolet light.

16. The display device according to claim 1, wherein
a visible light cut filter is arranged in the adjacent region.

17. The display device according to claim 2, wherein
the inner peripheral adjacent region is a corner region of the display region.

18. An electronic apparatus comprising:
a display device including a display region in which a display pixel that emits visible light is arranged, and an adjacent region in which an invisible light emitting pixel that emits at least invisible light in visible light and invisible light is arranged, the adjacent region being adjacent to the display region along an edge of the display region;
an imaging device that captures an image of invisible light; and
an optical element that guides the invisible light from the adjacent region of the display device to a user and guides invisible light reflected by the user to the imaging device.

19. The electronic apparatus according to claim 18, wherein
the imaging device is arranged near the display device.

20. The electronic apparatus according to claim 18, wherein
the imaging device is arranged at a position away from the display device.
